(19) United States
(12) Patent Application Publication
(10) Pub. No.: US 2024/0107898 A1
(43) Pub. Date: Mar. 28, 2024

(54) SUPERCONDUCTING LAYER JOINT STRUCTURE, SUPERCONDUCTING WIRE, SUPERCONDUCTING COIL, AND SUPERCONDUCTING DEVICE

(71) Applicant: KABUSHIKI KAISHA TOSHIBA, Tokyo (JP)

(72) Inventors: Tomoko EGUCHI, Yokohama Kanagawa (JP); Yasushi HATTORI, Kawasaki Kanagawa (JP); Masaya HAGIWARA, Yokohama Kanagawa (JP); Keiko ALBESSARD, Yokohama Kanagawa (JP)

(73) Assignee: KABUSHIKI KAISHA TOSHIBA, Tokyo (JP)

(21) Appl. No.: 18/180,576

(22) Filed: Mar. 8, 2023

(30) Foreign Application Priority Data
Sep. 20, 2022 (JP) 2022-148769

(51) Int. Cl. H10N 60/01; H01F 6/06; H10N 60/85

(52) U.S. Cl. CPC H10N 60/0324; H01F 6/06; H10N 60/0801; H10N 60/858

(57) ABSTRACT

A superconducting layer joint structure of embodiments includes: a first superconducting layer; a second superconducting layer; and a joint layer provided between the first superconducting layer and the second superconducting layer and containing a plurality of crystal particles containing a rare earth element (RE), barium (Ba), copper (Cu), and oxygen (O). The plurality of crystal particles includes at least one first particle. The at least one first particle has a first inner region and a first outer region. The first inner region is disposed inside the first superconducting layer. The first outer region is disposed outside the first superconducting layer.

### CROSS-REFERENCE TO RELATED APPLICATION

This application is based upon and claims the benefit of priority from Japanese Patent Application No. 2022-148769, filed on Sep. 20, 2022, the entire contents of which are incorporated herein by reference.

### FIELD

Embodiments described herein relate generally to a superconducting layer joint structure, a superconducting wire, a superconducting coil, and a superconducting device.

### BACKGROUND

For example, in a nuclear magnetic resonance (NMR) apparatus or a magnetic resonance imaging (MRI) apparatus, a superconducting coil is used to generate a strong magnetic field. The superconducting coil is formed by winding a superconducting wire around a winding frame.

In order to lengthen the superconducting wire, for example, a plurality of superconducting wires are connected to each other. For example, the ends of two superconducting wires are connected to each other by using a joint structure. The joint structure for jointing the superconducting wires to each other is required to have a low electrical resistance and a high mechanical strength.

### BRIEF DESCRIPTION OF THE DRAWINGS

FIG. 1 is a schematic cross-sectional view of a superconducting layer joint structure according to a first embodiment;

FIG. 2 is an enlarged schematic cross-sectional view of a part of a joint layer according to the first embodiment;

FIG. 3 is a diagram showing the particle diameter distribution of crystal particles contained in the joint layer according to the first embodiment;

FIG. 4 is an enlarged schematic cross-sectional view of a first particle in the joint layer according to the first embodiment;

FIG. 5 is an enlarged schematic cross-sectional view of a part of a joint layer in a comparative example;

FIG. 6 is an enlarged schematic cross-sectional view of a part of a joint layer in a modification example of the first embodiment;

FIG. 7 is a schematic cross-sectional view of a superconducting wire according to a second embodiment;

FIG. 8 is an enlarged schematic cross-sectional view of a part of a first joint layer according to the second embodiment;

FIG. 9 is an enlarged schematic cross-sectional view of a part of a second joint layer according to the second embodiment;

FIG. 10 is a schematic cross-sectional view of a first modification example of the superconducting wire according to the second embodiment;

FIG. 11 is a schematic cross-sectional view of a second modification example of the superconducting wire according to the second embodiment;

FIG. 12 is a schematic cross-sectional view of a third modification example of the superconducting wire according to the second embodiment;

FIG. 13 is a schematic cross-sectional view of a fourth modification example of the superconducting wire according to the second embodiment;

FIG. 14 is a schematic perspective view of a superconducting coil according to a third embodiment;

FIG. 15 is a schematic cross-sectional view of the superconducting coil according to the third embodiment; and

FIG. 16 is a block diagram of a superconducting device according to a fourth embodiment.

### DETAILED DESCRIPTION

A superconducting layer joint structure of embodiments includes: a first superconducting layer; a second superconducting layer; and a joint layer provided between the first superconducting layer and the second superconducting layer and containing a plurality of crystal particles containing a rare earth element (RE), barium (Ba), copper (Cu), and oxygen (O). The plurality of crystal particles includes at least one first particle. The at least one first particle has a first inner region and a first outer region. The first inner region is disposed inside the first superconducting layer. The first outer region is disposed outside the first superconducting layer.

Hereinafter, embodiments will be described with reference to the diagrams. In the following description, the same or similar members and the like may be denoted by the same reference numerals, and the description of the members and the like once described may be omitted as appropriate.

In this specification, the “particle diameter” of each particle or the like is the long diameter of the particle unless otherwise specified. The long diameter of the particle is the maximum length among the lengths between arbitrary two points on the circumference of the particle. In addition, the short diameter of the particle is the length of a line segment that passes through the midpoint of a line segment corresponding to the long diameter, is perpendicular to the line segment, and has both ends at the outer periphery of the particle. In addition, the aspect ratio of the particle is the ratio (long diameter/short diameter) of the long diameter to the short diameter of the particle. The long and short diameters of the particle can be calculated, for example, by image analysis of scanning electron microscope images (SEM images). In addition, the cross-sectional area of the particle can be calculated, for example, by image analysis of scanning electron microscope images.

Detection of elements contained in a particle or the like and measurement of atomic concentrations of the elements can be performed by using, for example, energy dispersive X-ray spectroscopy (EDX) or wavelength dispersive X-ray spectroscopy (WDX). In addition, identification of substances contained in a particle or the like can be performed by using, for example, a powder X-ray diffraction method.

### First Embodiment

A superconducting layer joint structure according to a first embodiment includes: a first superconducting layer; a second superconducting layer; and a joint layer provided between the first superconducting layer and the second superconducting layer and containing a plurality of crystal particles containing a rare earth element (RE), barium (Ba), copper (Cu), and oxygen (O). The plurality of crystal particles includes at least one first particle. The at least one first particle has a first inner region and a first outer region. The first inner region is disposed inside the first superconducting layer. The first outer region is disposed outside the first superconducting layer.

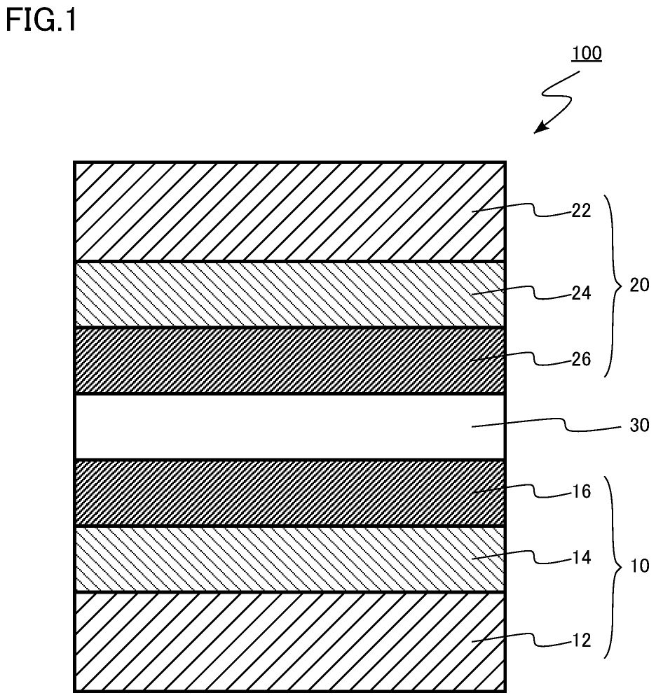

FIG. 1 is a schematic cross-sectional view of the superconducting layer joint structure according to the first embodiment. A joint structure 100 according to the first embodiment is a structure that physically and electrically joints two superconducting layers to each other. For example, the joint structure 100 is used to lengthen superconducting wires by jointing two superconducting wires to each other.

The joint structure 100 includes a first superconducting member 10, a second superconducting member 20, and a joint layer 30. The joint structure 100 is a structure in which a first superconducting member 10 and a second superconducting member 20 are connected to each other by a joint layer 30. The joint layer 30 is provided between the first superconducting member 10 and the second superconducting member 20.

The first superconducting member 10 includes a first substrate 12, a first intermediate layer 14, and a first superconducting layer 16. The second superconducting member 20 includes a second substrate 22, a second intermediate layer 24, and a second superconducting layer 26.

The first substrate 12 is, for example, a metal. The first substrate 12 is, for example, a nickel alloy or a copper alloy. The first substrate 12 is, for example, a nickel-tungsten alloy.

The first superconducting layer 16 is, for example, an oxide superconducting layer. The first superconducting layer 16 contains, for example, a rare earth element (RE), barium (Ba), copper (Cu), and oxygen (O). For example, the first superconducting layer 16 contains at least one rare earth element (RE) in a group consisting of yttrium (Y), lanthanum (La), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

The first superconducting layer 16 has, for example, a chemical composition represented by (RE)Ba₂Cu₃O₆ (RE is a rare earth element, 6≤δ≤7). Specifically, the first superconducting layer 16 has a chemical composition represented by, for example, GdBa₂Cu₃O₆ (6≤δ≤7), YBa₂Cu₃O₆ (6≤δ≤7), or EuBa₂Cu₃O₆ (6≤δ≤7).

The first superconducting layer 16 contains, for example, a single crystal having a perovskite structure.

For example, the first superconducting layer 16 is formed on the first intermediate layer 14 by using a metal organic decomposition method (MOD method), a pulsed laser deposition method (PLD method), or a metal organic chemical vapor deposition method (MOCVD method).

The first intermediate layer 14 is provided between the first substrate 12 and the first superconducting layer 16. The first intermediate layer 14 has a function of improving the crystal orientation of the first superconducting layer 16 formed on the first intermediate layer 14.

The first intermediate layer 14 contains, for example, a rare earth oxide. The first intermediate layer 14 has, for example, a stacked structure of a plurality of films. For example, the first intermediate layer 14 has a structure in which yttrium oxide (Y₂O₃), yttria-stabilized zirconia (YSZ), and cerium oxide (CeO₂) are stacked from the first substrate 12 side.

The second substrate 22 is, for example, a metal. The second substrate 22 is, for example, a nickel alloy or a copper alloy. The second substrate 22 is, for example, a nickel-tungsten alloy.

The second superconducting layer 26 is, for example, an oxide superconducting layer. The second superconducting layer 26 contains, for example, a rare earth element (RE), barium (Ba), copper (Cu), and oxygen (O). For example, the second superconducting layer 26 contains at least one rare earth element (RE) in a group consisting of yttrium (Y), lanthanum (La), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

The second superconducting layer 26 has, for example, a chemical composition represented by (RE)Ba₂Cu₃O₆ (RE is a rare earth element, 6≤δ≤7). The second superconducting layer 26 has a chemical composition represented by, for example, GdBa₂Cu₃O₆ (6≤δ≤7), YBa₂Cu₃O₆ (6≤δ≤7), or EuBa₂Cu₃O₆ (6≤δ≤7).

The second superconducting layer 26 contains, for example, a single crystal having a perovskite structure.

For example, the second superconducting layer 26 is formed on the second intermediate layer 24 by using an MOD method, a PLD method, or an MOCVD method.

The second intermediate layer 24 is provided between the second substrate 22 and the second superconducting layer 26. The second intermediate layer 24 has a function of improving the crystal orientation of the second superconducting layer 26 formed on the second intermediate layer 24.

The second intermediate layer 24 contains, for example, a rare earth oxide. The second intermediate layer 24 has, for example, a stacked structure of a plurality of films. For example, the second intermediate layer 24 has a structure in which yttrium oxide (Y₂O₃), yttria-stabilized zirconia (YSZ), and cerium oxide (CeO₂) are stacked from the second substrate 22 side.

The joint layer 30 is provided between the first superconducting layer 16 and the second superconducting layer 26. The joint layer 30 is in contact with the first superconducting layer 16. The joint layer 30 is in contact with the second superconducting layer 26.

The joint layer 30 is an oxide superconducting layer. The joint layer 30 contains a rare earth element (RE), barium (Ba), copper (Cu), and oxygen (O). For example, the joint layer 30 contains at least one rare earth element (RE) in a group consisting of yttrium (Y), lanthanum (La), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

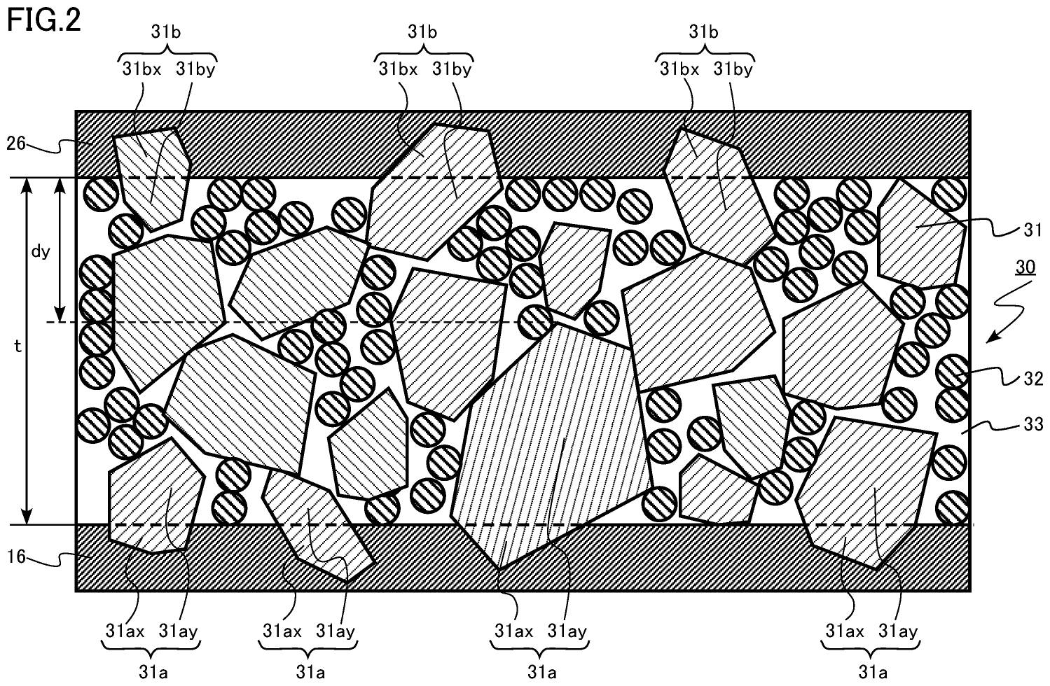

FIG. 2 is an enlarged schematic cross-sectional view of a part of the joint layer according to the first embodiment. FIG. 2 is a cross section perpendicular to the surface of the first superconducting layer 16.

The joint layer 30 contains a plurality of crystal particles. The joint layer 30 contains a first crystal particle 31 and a second crystal particle 32. The joint layer 30 may include a void 33. The joint layer 30 is formed by sintering the first crystal particle 31 and the second crystal particle 32.

The first crystal particle 31 and the second crystal particle 32 are examples of a crystal particle.

The first crystal particles 31 include at least one first particle 31a. In addition, the first crystal particles 31 include at least one second particle 31b.

The joint layer 30 is, for example, porous. For example, there is a void 33 between particles contained in the joint layer 30. There may be no void 33 in the joint layer 30.

The first crystal particle 31 contains a rare earth element (RE), barium (Ba), copper (Cu), and oxygen (O). The first crystal particle 31 is a rare earth oxide. The first crystal particle 31 is, for example, a single crystal or polycrystal having a perovskite structure.

The first crystal particle 31 has, for example, a chemical composition represented by (RE)Ba₂Cu₃O_{δ} (RE is a rare earth element, 6≤δ≤7). Specifically, the first crystal particle 31 has a chemical composition represented by, for example, GdBa₂Cu₃O₆ (6≤δ≤7), YBa₂Cu₃O₆ (6≤δ≤7), or EuBa₂Cu₃O₆ (6≤δ≤7).

The first crystal particle 31 is a superconductor.

The first crystal particle 31 has, for example, a plate shape or a flat shape. The flat shape means that the aspect ratio of the particle is equal to or more than 2. The aspect ratio of the particle is the ratio (long diameter/short diameter) of the long diameter to the short diameter of the particle.

The particle diameter of the first crystal particle 31 is, for example, equal to or more than 500 nm and equal to or less than 5 μm. The median of the particle diameter of the first crystal particle 31 is, for example, equal to or more than 500 nm and equal to or less than 5 μm.

The second crystal particles 32 contains a rare earth element (RE), barium (Ba), copper (Cu), and oxygen (O). The second crystal particle 32 is a rare earth oxide. The second crystal particle 32 is, for example, a single crystal or polycrystal having a perovskite structure. The second crystal particle 32 has, for example, a chemical composition represented by (RE)Ba₂Cu₃O₆ (RE is a rare earth element, 6≤δ≤7).

The second crystal particle 32 is, for example, a superconductor.

The second crystal particle 32 contains, for example, the same rare earth element as in the first crystal particle 31. The chemical composition of the second crystal particle 32 is the same as the chemical composition of the first crystal particle 31, for example.

The second crystal particle 32 may contain, for example, a rare earth element different from that of the first crystal particle 31. The chemical composition of the second crystal particle 32 may be different from the chemical composition of the first crystal particle 31, for example.

The second crystal particle 32 has, for example, a spherical shape or an amorphous shape. The aspect ratio of the second crystal particle 32 is less than 2, for example.

The particle diameter of the second crystal particle 32 is less than the particle diameter of the first crystal particle 31. For example, the median of the particle diameter of the second crystal particle 32 is less than the median of the particle diameter of the first crystal particle 31.

The particle diameter of the second crystal particle 32 is, for example, equal to or more than 10 nm and less than 1 μm. The median of the particle diameter of the second crystal particle 32 is, for example, equal to or more than 10 nm and less than 1 μm.

The median of the particle diameter of the first crystal particle 31 is, for example, equal to or more than 10 times and equal to or less than 1000 times the median of the particle diameter of the second crystal particle 32.

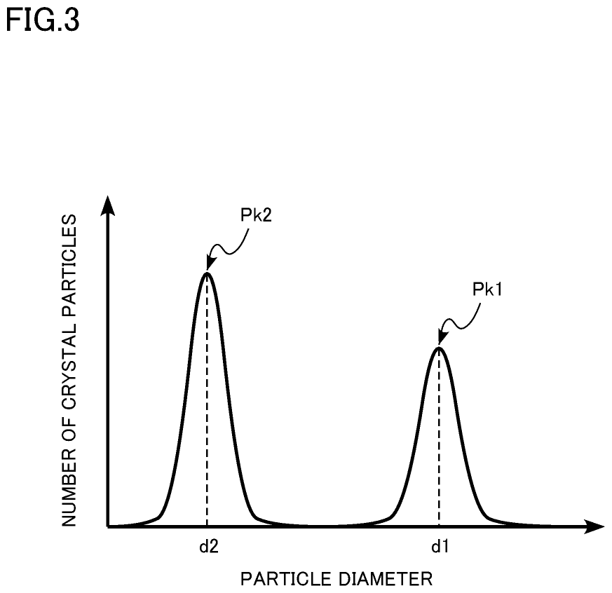

FIG. 3 is a diagram showing the particle diameter distribution of crystal particles contained in the joint layer according to the first embodiment. FIG. 3 shows the particle diameter distribution of the first crystal particle 31 and the second crystal particle 32 contained in the joint layer 30.

As shown in FIG. 3, the particle diameter distribution of crystal particles contained in the joint layer 30 includes a bimodal distribution. The bimodal distribution has a first distribution including a first peak (Pk1 in FIG. 3) and a second distribution including a second peak (Pk2 in FIG. 3).

In addition, the particle diameter distribution of crystal particles contained in the joint layer 30 may be a multimodal distribution having three or more peaks.

The particle diameter of the crystal particle corresponding to the first peak Pk1 is a first particle diameter (d1 in FIG. 3). The particle diameter of the crystal particle corresponding to the second peak Pk2 is a second particle diameter (d2 in FIG. 3).

The first particle diameter d1 is larger than the second particle diameter d2. The first particle diameter d1 is, for example, equal to or more than 10 times and equal to or less than 1000 times the second particle diameter d2.

The first particle diameter d1 is, for example, equal to or more than 500 nm and equal to or less than 5 μm. The second particle diameter d2 is, for example, equal to or more than 10 nm and less than 1 μm.

In the first distribution, the first crystal particle 31 is mainly included. In the second distribution, the second crystal particle 32 is mainly included.

Examples of a crystal particle having a particle diameter corresponding to the first distribution include a plate-shaped crystal particle or a flat crystal particle. For example, among the crystal particles having a particle diameter corresponding to the first distribution, the number of plate-shaped or flat crystal particles is larger than the number of crystal particles having other shapes.

Examples of a crystal particle having a particle diameter corresponding to the second distribution include a spherical crystal particle or an amorphous crystal particle. For example, among the crystal particles having a particle diameter corresponding to the second distribution, the number of spherical or amorphous crystal particles is larger than the number of crystal particles having other shapes.

The first crystal particles 31 include at least one first particle 31a. That is, at least one of the first crystal particles 31 is the first particle 31a. In addition, the first crystal particles 31 include at least one second particle 31b. That is, at least one of the first crystal particles 31 is the second particle 31b. The first particle 31a and the second particle 31b are included in, for example, a first distribution of the particle diameter distribution of crystal particles contained in the joint layer 30.

The first particle 31a has a first inner region 31ax and a first outer region 31ay.

The first inner region 31ax is disposed inside the first superconducting layer 16. The first inner region 31ax is present closer to the first superconducting layer 16 than the interface between the first superconducting layer 16 and the joint layer 30. The first inner region 31ax is buried in the first superconducting layer 16, for example. The first inner region 31ax and the first superconducting layer 16 are bonded to each other, for example.

The first outer region 31ay is disposed outside the first superconducting layer 16. The first outer region 31ay is present closer to the joint layer 30 than the interface between the first superconducting layer 16 and the joint layer 30. The first outer region 31ay is disposed inside the joint layer 30. Therefore, one first particle 31a is present over both the first superconducting layer 16 and the joint layer 30.

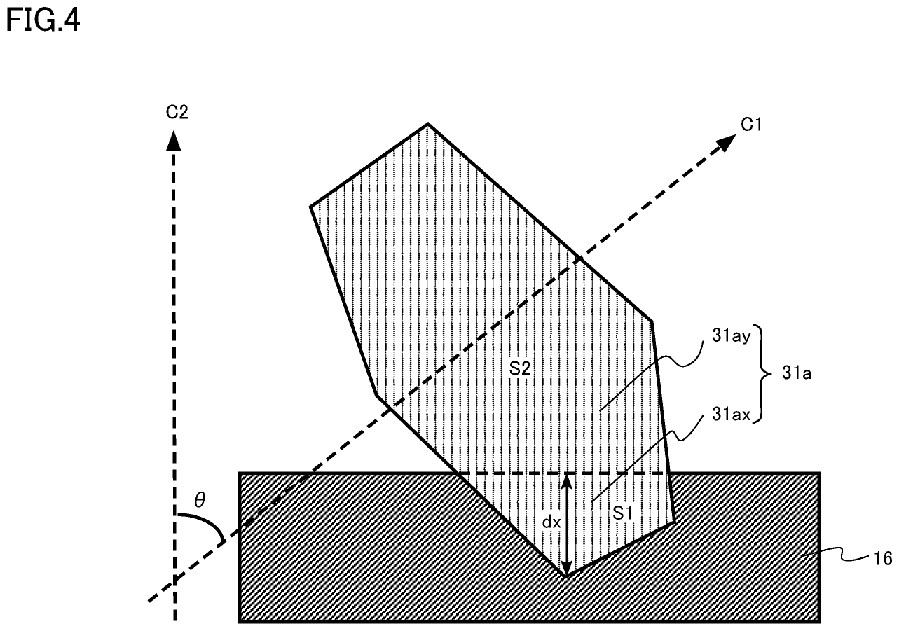

FIG. 4 is an enlarged schematic cross-sectional view of the first particle 31a in the joint layer according to the first embodiment. FIG. 4 shows a cross section perpendicular to the surface of the first superconducting layer 16. In addition, the surface of the first superconducting layer 16 means an interface between the first superconducting layer 16 and the joint layer 30.

The fact that the first particle 31a has the first inner region 31ax and the first outer region 31ay can be checked from an observed image obtained by observing a cross section, which is perpendicular to the surface of the first superconducting layer 16 and includes the joint layer 30, using a scanning electron microscope (SEM) or the like, for example.

If it is unclear whether or not the first particle 31a is buried in the first superconducting layer 16, the fact that the first particle 31a has the first inner region 31ax and the first outer region 31ay can be checked by observing the crystal orientation of the first particle 31a and the crystal orientation of the first superconducting layer 16 disposed therearound by further using a scanning transmission electron microscope (STEM) or a transmission electron microscope (TEM).

In the cross section perpendicular to the surface of the first superconducting layer 16, the ratio α (S1/(S1+S2)) of the area (S1 in FIG. 4) of the first inner region 31ax to the sum (S1+S2) of the area of the first inner region 31ax and the area (S2 in FIG. 4) of the first outer region 31ay is, for example, equal to or more than 10% and equal to or less than 90%.

When the area ratio α is equal to or more than 10% and equal to or less than 90%, the contact resistance at the interface between the first superconducting layer 16 and the joint layer 30 is reduced. Therefore, a current path from the first superconducting layer 16 to the first particle 31a is formed, and the amount of current flowing from the first superconducting layer 16 to the joint layer 30 increases. In addition, when the area ratio α is equal to or more than 10% and equal to or less than 90%, the first particle 31a is fixed to the first superconducting layer 16, and the peeling of the joint layer 30 from the first superconducting layer 16 can be suppressed by the anchoring effect. That is, it is possible to form a joint structure having a low electrical resistance and a high mechanical strength.

If the area ratio α is less than 10%, the effect of reducing the electrical resistance and the effect of increasing the mechanical strength may not be obtained. If the area ratio α is more than 90%, the first particle 31a may block the current flowing in a direction, which is parallel to the surface of the first superconducting layer 16, in the first superconducting layer 16.

In a cross section perpendicular to the surface of the first superconducting layer 16, the area S2 of the first outer region 31ay is larger than the area S1 of the first inner region 31ax, for example.

The areas S1 and S2 can be calculated from an observed image obtained by observing a cross section, which is perpendicular to the surface of the first superconducting layer 16 and includes the joint layer 30, using a scanning electron microscope (SEM) or the like, for example. Specifically, the magnification of the SEM is set to 2000 times or more and 10000 times or less for a predetermined sample X, and in one SEM image A, all particles (particles corresponding to 31a in FIG. 2) that are clearly buried in the first superconducting layer 16 among the first crystal particles 31 are selected. However, particles with a depth (dx in FIG. 4) of the first inner region 31ax from the surface of the first superconducting layer 16, which is less than 50 nm, are excluded from the selection.

Then, the outermost line of the selected first particle 31a is drawn. Then, a straight line is drawn on the surface of the first superconducting layer 16, that is, on the interface between the first superconducting layer 16 and the joint layer 30. Finally, the areas of S1 and S2 surrounded by the outermost peripheral line of the first particle 31a and the straight line of the surface of the first superconducting layer 16 are calculated, and the area ratio α (S1/(S1+S2)) is calculated for each of the first particles 31a. S1 and S2 can also be calculated by using commercially available image analysis software.

Then, in the SEM image A, all the first particle 31a for which it is not clear whether or not these are buried in the first superconducting layer 16, among the first crystal particle 31, are selected. For these particles, the crystal orientation of the first particle 31a and the crystal orientation of the first superconducting layer 16 disposed therearound are observed by further using a scanning transmission electron microscope (STEM) or a transmission electron microscope (TEM).

The first superconducting layer 16 is a thin film with high crystal orientation in which the c-axis is aligned in a direction perpendicular to the surface of the first superconducting layer 16. Therefore, even if the first particle 31a, which is a bulk body, is buried in the first superconducting layer 16 in the process of forming the joint structure, the crystal orientations of the two do not completely match, and the two do not completely assimilate. In other words, the boundary with different directions of crystal orientations can be defined as the outermost periphery of the first particle 31a.

After drawing the line on the outermost periphery of the first particle 31a, S1, S2, and a are calculated for each of the first particles 31a on the STEM image or the TEM image in the same manner as the calculation method for the SEM image A described above. However, particles with a depth (dx in FIG. 4) of the first inner region 31ax from the surface of the first superconducting layer 16, which is less than 50 nm, as a result of subtracting the outermost periphery of the first particle 31a are excluded from the calculation.

From the above, in one SEM image A, S1 can be obtained for each of the first particle 31a, and the average value thereof is assumed to be S1a. Similarly, in the SEM image A, S2 can be obtained for each of the first particle 31a, and the average value thereof is assumed to be S2a. Similarly, in the SEM image A, the area ratio (S1/(S1+S2)) can be calculated for each of the first particle 31a, and the average value thereof is assumed to be the “average value αa of the area ratio α”.

In addition, SEM images B, C, D, and E of four different fields of view in the same sample X are prepared, and S1b, S2b, S1c, S2c, S1d, S2d, S1e, S2e, αb, αc, αd, and αe are calculated in the same procedure. Finally, the average value of S1a to S1e is defined as S1 in the sample X, the average value of S2a to S2e is defined as S2 in sample X, and the average value of αa to αe is defined as the “ratio of the area of the first inner region to the sum of the area of the first inner region and the area of the first outer region in the sample X”.

The angle (θ in FIG. 4) between the c-axis direction (dotted arrow C1 in FIG. 4) of the first particle 31a and the c-axis direction (dotted arrow C2 in FIG. 4) of the first superconducting layer 16 is, for example, equal to or more than 15° and equal to or less than 90°. For example, the median of the angle (θ in FIG. 4) between the c-axis direction (dotted arrow C1 in FIG. 4) of the first particle 31a and the c-axis direction (dotted arrow C2 in FIG. 4) of the first superconducting layer 16 is, for example, equal to or more than 15° and equal to or less than 90°.

These c-axis directions can be checked from STEM observation or TEM observation.

The particle diameter of the first particle 31a is, for example, equal to or more than 500 nm and equal to or less than 5 μm. In addition, the median of the particle diameter of the first particle 31a is, for example, equal to or more than 500 nm and equal to or less than 5 μm.

The depth (dx in FIG. 4) of the first inner region 31ax from the surface of the first superconducting layer 16 is, for example, equal to or more than 100 nm and equal to or less than 1.5 μm.

The distance (dy in FIG. 2) between the first particle 31a and the second superconducting layer 26 is, for example, equal to or less than ½ (one half) of the distance (t in FIG. 2) between the first superconducting layer 16 and the second superconducting layer 26. In addition, the distance t between the first superconducting layer 16 and the second superconducting layer 26 is equal to the thickness of the joint layer 30.

In a cross section perpendicular to the surface of the first superconducting layer 16, the number of first particles 31a present within the range of 1 mm along the surface is, for example, equal to or more than 10 and equal to or less than 100.

The second particle 31b has a second inner region 31bx and a second outer region 31by.

The second inner region 31bx is disposed inside the second superconducting layer 26. The second inner region 31bx is present closer to the second superconducting layer 26 than the interface between the second superconducting layer 26 and the joint layer 30. The second inner region 31bx is buried in the second superconducting layer 26, for example. The second inner region 31bx and the second superconducting layer 26 are bonded to each other, for example.

The second outer region 31by is disposed outside the second superconducting layer 26. The second outer region 31by is present closer to the joint layer 30 than the interface between the second superconducting layer 26 and the joint layer 30. The second outer region 31by is disposed inside the joint layer 30.

In the cross section perpendicular to the surface of the second superconducting layer 26, the ratio of the area of the second inner region 31bx to the sum of the area of the second inner region 31bx and the area of the second outer region 31by is, for example, equal to or more than 10% and equal to or less than 90%.

When the area ratio α is equal to or more than 10% and equal to or less than 90%, the contact resistance at the interface between the second superconducting layer 26 and the joint layer 30 is reduced. Therefore, a current path from the second superconducting layer 26 to the second particle 31b is formed, and the amount of current flowing from the second superconducting layer 26 to the joint layer 30 increases. In addition, when the area ratio α is equal to or more than 10% and equal to or less than 90%, the second particle 31b is fixed to the second superconducting layer 26, and the peeling of the joint layer 30 from the second superconducting layer 26 can be suppressed by the anchoring effect. That is, it is possible to form a joint structure having a low electrical resistance and a high mechanical strength.

If the area ratio α is less than 10%, the effect of reducing the electrical resistance and the effect of increasing the mechanical strength may not be obtained. If the area ratio α is more than 90%, the second particle 31b may block the current flowing in a direction, which is parallel to the surface of the second superconducting layer 26, in the second superconducting layer 26.

In a cross section perpendicular to the surface of the second superconducting layer 26, the area of the second outer region 31by is larger than the area of the second inner region 31bx, for example. The area of 31by, the area of 31bx, and the area ratio can be calculated by using the method described above.

The angle between the c-axis direction of the second particle 31b and the c-axis direction of the second superconducting layer 26 is, for example, equal to or more than 15° and equal to or less than 90°. For example, the median of the angle between the c-axis direction of the second particle 31b and the c-axis direction of the second superconducting layer 26 is, for example, equal to or more than 15° and equal to or less than 90°. As described above, the c-axis directions can be checked from STEM observation or TEM observation.

The particle diameter of the second particle 31b is, for example, equal to or more than 500 nm and equal to or less than 5 μm. In addition, the median of the particle diameter of the second particle 31b is, for example, equal to or more than 500 nm and equal to or less than 5 μm.

The depth of the second inner region 31bx from the surface of the second superconducting layer 26 is, for example, equal to or more than 100 nm and equal to or less than 1.5 μm.

The distance between the second particle 31b and the first superconducting layer 16 is, for example, equal to or less than ½ of the distance (t in FIG. 2) between the first superconducting layer 16 and the second superconducting layer 26. In addition, the distance t between the first superconducting layer 16 and the second superconducting layer 26 is equal to the thickness of the joint layer 30.

In a cross section perpendicular to the surface of the second superconducting layer 26, the number of second particles 31b present within the range of 1 mm along the surface is, for example, equal to or more than 10 and equal to or less than 100.

Next, an example of a method for manufacturing the superconducting layer joint structure according to the first embodiment will be described.

First, an oxide superconductor containing a rare earth element (RE), barium (Ba), copper (Cu), and oxygen (O) is formed.

The oxide superconductor is formed by using a solid state reaction method. In forming the oxide superconductor, powders of Gd₂O₃, BaCO₃, and CuO are mixed and compressed to manufacture a powder compact. By sintering the powder compact, an oxide superconductor having a composition of GdBa₂Cu₃O₆ (6≤δ≤7) is formed. Gd may be replaced with Y, La, Nd, Sm, Eu, Dy, Ho, Er, Tm, Yb, and Lu.

The first crystal particle 31 is formed by pulverizing the oxide superconductor.

Then, the joint layer 30 is formed by using the MOD method.

An organometallic salt solution is manufactured by using the powders of Gd(OCOCH₃)₂, Ba(OCOCH₃)₂, and Cu(OCOCH₃)₂. The first crystal particle 31 is mixed with the manufactured organometallic salt solution. Gd may be replaced with Y, La, Nd, Sm, Eu, Dy, Ho, Er, Tm, Yb, and Lu.

Then, the organometallic salt solution mixed with the first crystal particle 31 is applied onto the first superconducting layer 16. Then, the applied organometallic salt solution is baked in a state in which the applied organometallic salt solution is interposed between the first superconducting layer 16 and the second superconducting layer 26, thereby forming the joint layer 30. When the joint layer 30 is formed by baking, the first superconducting layer 16 and the second superconducting layer 26 that are superimposed are pressed in a direction from the second superconducting layer 26 toward the first superconducting layer 16.

The second crystal particle 32 is formed by baking the organometallic salt solution. The particle diameter of the second crystal particle 32 is less than the particle diameter of the first crystal particle 31.

By controlling the mixing ratio of the first crystal particle 31 and the organometallic salt solution and adjusting the pressure and baking temperature when pressing the first superconducting layer 16 and the second superconducting layer 26 that are superimposed, the first particle 31a and the second particle 31b can be formed in the joint layer 30. It is known that, as the pressure value applied to the first superconducting layer 16 and the second superconducting layer 26 that are superimposed increases and the baking temperature increases, the bonding reaction between the joint layer 30 and the first superconducting layer 16, and the second superconducting layer 26 progresses and accordingly a strong joint structure is obtained. However, if the pressure value during baking is doubled, for example, cracks may occur in the first superconducting layer 16 or the second superconducting layer 26, degrading joint characteristics.

Therefore, for example, the pressure value is increased once before baking to create a starting point at which the superconducting powder contained in the slurry is buried in the oxide superconducting layer, that is, a starting point at which bonding starts. By creating the starting point where bonding starts, the superconducting powder can be buried in the oxide superconducting layer without increasing the pressure value at the time of baking.

In addition, by adjusting the pressure and the baking temperature when pressing, the area ratio and the like between the first inner region 31ax and the first outer region 31ay of the first particle 31a can be adjusted to a desired value. In addition, by adjusting the pressure and the baking temperature when pressing, the area ratio and the like between the second inner region 31bx and the second outer region 31by of the second particle 31b can be adjusted to a desired value.

The mixing ratio of the first crystal particle and the organometallic salt solution is preferably, for example, first crystal particle:organometallic salt solution=4:1 to 1:4. The pressure when pressing is preferably equal to or more than 0.8 and equal to or less than 2.2 in the case of a relative pressure value before baking and equal to or more than 0.8 and equal to or less than 1.5 in the case of a relative pressure value at the time of baking. The baking temperature is preferably equal to or more than 700° C. and equal to or less than 850° C. A desired joint layer can be manufactured by appropriately selecting the pressure and the baking temperature from the ranges.

According to the method described above, it is considered that the first crystal particle 31 is buried in the first superconducting layer 16 or the second superconducting layer 26 by the pressure at the time of baking and accordingly, the first particle 31a and the second particle 31b are formed. In addition, according to the method described above, it is considered that a chemical reaction between the first crystal particle 31 and the first superconducting layer 16 or between the first crystal particle 31 and the second superconducting layer 26 progresses due to pressing at the time of baking and accordingly, the first particle 31a and the second particle 31b are formed.

By the method described above, the first superconducting layer 16 and the second superconducting layer 26 are connected to each other. By the method described above, the superconducting layer joint structure 100 according to the first embodiment is formed.

Next, the function and the like of the superconducting layer joint structure according to the first embodiment will be described.

For example, in a nuclear magnetic resonance (NMR) apparatus or a magnetic resonance imaging (MRI) apparatus, a superconducting coil is used to generate a strong magnetic field. The superconducting coil is formed by winding a superconducting wire around a winding frame.

In order to lengthen the superconducting wire, for example, a plurality of superconducting wires are connected to each other. For example, the ends of two superconducting wires are connected to each other by using a joint structure. The joint structure for jointing the superconducting wires to each other is required to have a low electrical resistance and a high mechanical strength.

In the superconducting layer joint structure 100 according to the first embodiment, the joint layer 30 that joints the first superconducting layer 16 and the second superconducting layer 26 to each other contains the first particle 31a and the second particle 31b. Since the joint layer 30 contains the first particle 31a and the second particle 31b, it is possible to realize the superconducting layer joint structure 100 having a low electrical resistance and a high mechanical strength. The details will be described below.

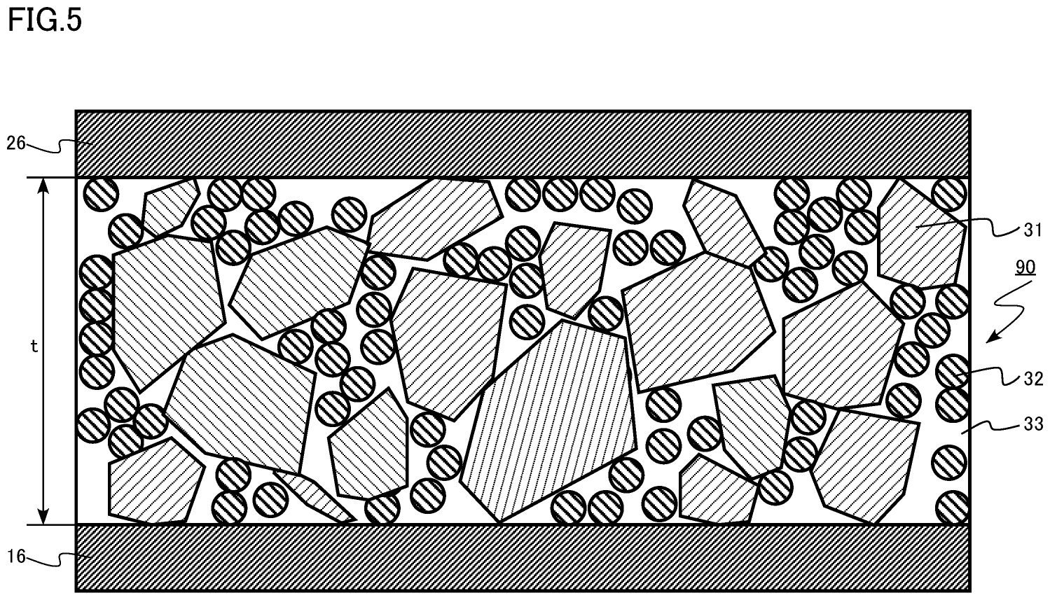

FIG. 5 is an enlarged schematic cross-sectional view of a part of a joint layer in a comparative example. FIG. 5 is a diagram corresponding to FIG. 2. A joint layer 90 in the comparative example is different from the joint layer 30 in the first embodiment in that the joint layer 90 does not contain the first particle 31a and the second particle 31b.

In the joint structure 100 according to the first embodiment, the first crystal particle 31 includes the first particle 31a having the first inner region 31ax. Since the first particle 31a has the first inner region 31ax, the contact area between the first particle 31a and the first superconducting layer 16 increases, and the contact resistance between the first particle 31a and the first superconducting layer 16 is reduced. Therefore, the electrical resistance of the joint structure 100 can be made even lower than that of the joint structure in the comparative example.

In addition, in the joint structure 100 according to the first embodiment, the first crystal particle 31 includes the second particle 31b having the second inner region 31bx. Since the second particle 31b had the second inner region 31bx, the contact area between the second particle 31b and the second superconducting layer 26 increases, and the contact resistance between the second particle 31b and the second superconducting layer 26 is reduced. Therefore, the electrical resistance of the joint structure 100 can be made even lower than that of the joint structure in the comparative example.

From the viewpoint of reducing the electrical resistance of the joint structure 100, the angle (θ in FIG. 4) between the c-axis direction (dotted arrow C1 in FIG. 4) of the first particle 31a and the c-axis direction (dotted arrow C2 in FIG. 4) of the first superconducting layer 16 is preferably equal to or more than 15°, more preferably equal to or more than 30°, and even more preferably equal to or more than 45°.

The current in the first particle 31a and the first superconducting layer 16 mainly flows in a plane perpendicular to the c-axis direction. The c-axis of the first superconducting layer 16 is oriented in a direction perpendicular to the surface of the first superconducting layer 16, as shown in FIG. 4. Therefore, the current in the first superconducting layer 16 mainly flows in a direction parallel to the surface of the first superconducting layer 16.

By inclining the c-axis direction of the first particle 31a to the c-axis direction of the first superconducting layer 16 as shown in FIG. 4, a component directed toward the second superconducting layer 26 in the current flowing through the first particle 31a is increased. Therefore, it is possible to reduce the electrical resistance of the joint structure 100.

For the same reason, the angle between the c-axis direction of the second particle 31b and the c-axis direction of the second superconducting layer 26 is preferably equal to or more than 15°, more preferably equal to or more than 30°, and even more preferably equal to or more than 45°.

From the viewpoint of reducing the electrical resistance of the joint structure 100, the distance (dy in FIG. 2) between the first particle 31a and the second superconducting layer 26 is preferably equal to or less than ½ of the distance (t in FIG. 2) between the first superconducting layer 16 and the second superconducting layer 26, more preferably equal to or less than ⅓, and even more preferably equal to or less than ¼. As the distance dy between the first particle 31a and the second superconducting layer 26 decreases, the electrical resistance between the first particle 31a and the second superconducting layer 26 decreases. Therefore, it is possible to reduce the electrical resistance of the joint structure 100.

For the same reason, the distance between the second particle 31b and the first superconducting layer 16 is preferably equal to or less than ½ of the distance (t in FIG. 2) between the first superconducting layer 16 and the second superconducting layer 26, more preferably equal to or less than ⅓, and even more preferably equal to or less than ¼.

From the viewpoint of reducing the electrical resistance of the joint structure 100, the area S2 of the first outer region 31ay is preferably larger than the area S1 of the first inner region 31ax. Since the area S2 of the first outer region 31ay is larger than the area S1 of the first inner region 31ax, the contribution of the first particle 31a to the current path in the joint layer 30 increases. Therefore, it is possible to reduce the electrical resistance of the joint structure 100.

For the same reason, the area of the second outer region 31by is preferably larger than the area of the second inner region 31bx.

For example, when manufacturing a superconducting coil by winding a superconducting wire having a joint structure of the comparative example shown in FIG. 5 around a winding frame, a stress is applied between the first superconducting layer 16 and the joint layer 90. If the mechanical strength of the interface between the first superconducting layer 16 and the joint layer 90 is not sufficient, the first superconducting layer 16 and the joint layer 90 may be peeled off at the interface when a stress is applied between the first superconducting layer 16 and the joint layer 90. Similarly, if the mechanical strength of the interface between the second superconducting layer 26 and the joint layer 90 is not sufficient, the second superconducting layer 26 and the joint layer 90 may be peeled off at the interface.

In the joint structure 100 according to the first embodiment, the first crystal particle 31 includes the first particle 31a having the first inner region 31ax and the first outer region 31ay. Since the first particle 31a is present between the first superconducting layer 16 and the joint layer 30, the first particle 31a exhibits an anchoring effect to increase the mechanical strength of the interface between the first superconducting layer 16 and the joint layer 30. Therefore, even when a stress is applied between the first superconducting layer 16 and the joint layer 30, the peeling of the first superconducting layer 16 and the joint layer 30 at the interface is suppressed. As a result, the joint structure 100 can have a higher mechanical strength than the joint structure of the comparative example.

In addition, in the joint structure 100 according to the first embodiment, the first crystal particle 31 includes the second particle 31b having the second inner region 31bx and the second outer region 31by. Therefore, for the same reason as in the case of the first particle 31a, even when a stress is applied between the second superconducting layer 26 and the joint layer 30, the peeling of the second superconducting layer 26 and the joint layer 30 at the interface is suppressed. As a result, the joint structure 100 can have a higher mechanical strength than the joint structure of the comparative example.

From the viewpoint of increasing the mechanical strength of the joint structure 100, the ratio (S1/(S1+S2)) of the area of the first inner region 31ax to the sum (S1+S2) of the area (S1 in FIG. 4) of the first inner region 31ax and the area (S2 in FIG. 4) of the first outer region 31ay is preferably equal to or more than 10%, more preferably equal to or more than 20%, and even more preferably equal to or more than 30%. By increasing the ratio of the area of the second inner region 31bx, the anchoring effect of the first particle 31a is enhanced. As a result, the mechanical strength of the joint structure 100 is increased.

For the same reason, the ratio of the area of the second inner region 31bx to the sum of the area of the second inner region 31bx and the area of the second outer region 31by is preferably equal to or more than 10%, more preferably equal to or more than 20%, and even more preferably equal to or more than 30%. S1, S2, and the area ratio can be calculated by using the method described above.

From the viewpoint of increasing the mechanical strength of the joint structure 100, the depth (dx in FIG. 4) of the first inner region 31ax from the surface of the first superconducting layer 16 is preferably equal to or more than 100 nm, more preferably equal to or more than 500 nm, and even more preferably equal to or more than 1 μm. Since the first inner region 31ax penetrates deep into the first superconducting layer 16, the anchoring effect of the first particle 31a is enhanced. As a result, the mechanical strength of the joint structure 100 is increased.

For the same reason, the depth of the second inner region 31bx from the surface of the second superconducting layer 26 is preferably equal to or more than 100 nm, more preferably equal to or more than 500 nm, and even more preferably equal to or more than 1 μm.

In a cross section perpendicular to the surface of the first superconducting layer 16, the number of first particles 31a present in the range of 1 mm along the surface is preferably equal to or more than 10, more preferably equal to or more than 20, and even more preferably equal to or more than 50. The interfacial resistance between the first superconducting layer 16 and the joint layer 30 is reduced by increasing the density of the first particle 31a. Therefore, the electrical resistance of the joint structure 100 is reduced. In addition, as the density of the first particle 31a increases, the anchoring effect of the first particle 31a increases. Therefore, the mechanical strength of the joint structure 100 is increased.

For the same reason, in a cross section perpendicular to the surface of the second superconducting layer 26, the number of second particles 31b present in the range of 1 mm along the surface is preferably equal to or more than 10, more preferably equal to or more than 20, and even more preferably equal to or more than 50.

As shown in FIG. 3, in the superconducting layer joint structure 100 according to the first embodiment, the particle diameter distribution of the crystal particles contained in the joint layer 30 includes a bimodal distribution. Since the joint structure 100 includes the first crystal particle 31 having a large particle diameter, the crystal particle interface occupying the joint layer 30 is reduced. Therefore, an increase in the electrical resistance of the joint layer 30 due to the interfacial resistance of the crystal particle interface is suppressed. As a result, the electrical resistance of the joint structure 100 is reduced.

In addition, in the superconducting layer joint structure 100 according to the first embodiment, the second crystal particle 32 having a small particle diameter fill the space between the first crystal particles 31 having large particle diameters. Interposition of the second crystal particle 32 increases the bonding strength between the first crystal particles 31. As a result, the mechanical strength of the joint layer 30 is increased, and the mechanical strength of the joint structure 100 is increased.

### Modification Example

A joint structure in a modification example of the first embodiment is different from the joint structure according to the first embodiment in that the first particle is in contact with the second superconducting layer or a part of the particle is also buried on the second superconducting layer side.

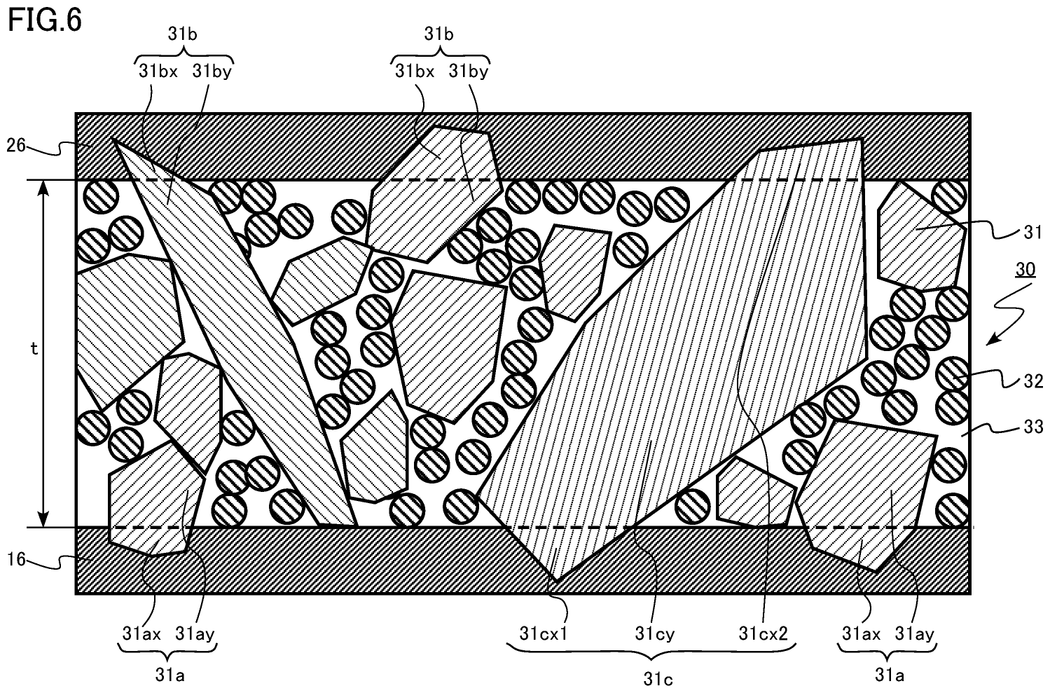

FIG. 6 is an enlarged schematic cross-sectional view of a part of a joint layer in a modification example of the first embodiment. FIG. 6 is a diagram corresponding to FIG. 2.

The joint layer 30 of the joint structure in the modification example includes the first particle 31a in contact with the second superconducting layer 26. In addition, the joint layer 30 of the joint structure in the modification example includes the second particle 31b in contact with the first superconducting layer 16. In addition, the joint layer 30 of the joint structure in the modification example may include a third particle 31c having a first inner region 31cx1 and a second inner region 31cx2 in addition to an outer region 31cy.

The particle diameter of the first particle 31a in contact with the second superconducting layer 26 is, for example, larger than the distance (t in FIG. 6) between the first superconducting layer 16 and the second superconducting layer 26. In addition, the particle diameter of the second particle 31b in contact with the first superconducting layer 16 is, for example, larger than the distance (t in FIG. 6) between the first superconducting layer 16 and the second superconducting layer 26. In addition, the particle diameter of the third particle 31c extending over both the first superconducting layer 16 and the second superconducting layer 26 is, for example, larger than the distance (t in FIG. 6) between the first superconducting layer 16 and the second superconducting layer 26.

The joint layer 30 of the joint structure in the modification example contains the first particle 31a in contact with the second superconducting layer 26, thereby further reducing the electrical resistance. In addition, the joint layer 30 of the joint structure in the modification example includes the second particle 31b in contact with the first superconducting layer 16, thereby further reducing the electrical resistance. In addition, the joint layer 30 of the joint structure in the modification example includes the third particle 31c extending over both the first superconducting layer 16 and the second superconducting layer 26, thereby further reducing the electrical resistance.

As described above, according to the superconducting layer joint structure according to the first embodiment, it is possible to realize a low electrical resistance and a high mechanical strength.

### Second Embodiment

A superconducting wire according to a second embodiment includes: a first superconducting wire including a first superconducting layer; a second superconducting wire including a second superconducting layer; a third superconducting layer; a first joint layer provided between the first superconducting layer and the third superconducting layer and containing a plurality of crystal particles containing a rare earth element (RE), barium (Ba), copper (Cu), and oxygen (O); and a second joint layer provided between the second superconducting layer and the third superconducting layer and containing a plurality of crystal particles containing a rare earth element (RE), barium (Ba), copper (Cu), and oxygen (O). The plurality of crystal particles contained in the first joint layer includes at least one first particle. The at least one first particle has a first inner region and a first outer region. The first inner region is disposed inside the first superconducting layer. The first outer region is disposed outside the first superconducting layer. In the superconducting wire according to the second embodiment, the superconducting layer joint structure according to the first embodiment is used as a structure for jointing the first superconducting wire and the second superconducting wire. Hereinafter, the description of a part of the content overlapping the first embodiment will be omitted.

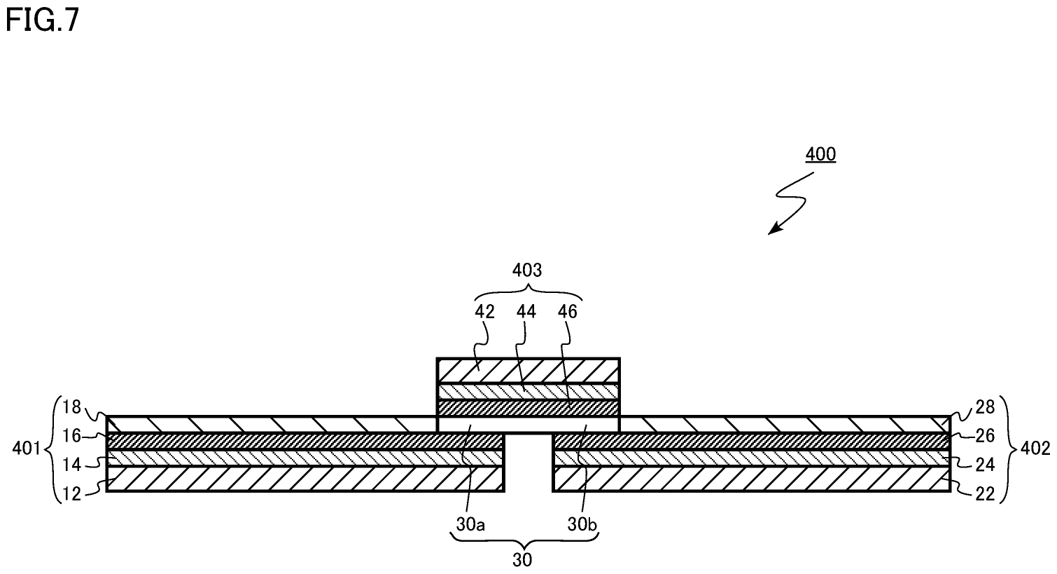

FIG. 7 is a schematic cross-sectional view of the superconducting wire according to the second embodiment. A superconducting wire 400 according to the second embodiment includes a first superconducting wire 401, a second superconducting wire 402, and a joint member 403. The superconducting wire 400 according to the second embodiment is lengthened by jointing the first superconducting wire 401 and the second superconducting wire 402 using the joint member 403.

The first superconducting wire 401 includes a first substrate 12, a first intermediate layer 14, a first superconducting layer 16, and a first protective layer 18. The second superconducting wire 402 includes a second substrate 22, a second intermediate layer 24, a second superconducting layer 26, and a second protective layer 28. The joint member 403 includes a third substrate 42, a third intermediate layer 44, and a third superconducting layer 46.

The first superconducting wire 401, the second superconducting wire 402, and the joint member 403 have the same structures as the first superconducting member 10 and the second superconducting member 20 in the first embodiment.

The joint layer 30 includes a first joint layer 30a and a second joint layer 30b.

The first joint layer 30a is provided between the first superconducting layer 16 and the third superconducting layer 46. The first joint layer 30a is in contact with the first superconducting layer 16. The first joint layer 30a is in contact with the third superconducting layer 46.

The second joint layer 30b is provided between the second superconducting layer 26 and the third superconducting layer 46. The second joint layer 30b is in contact with the second superconducting layer 26. The second joint layer 30b is in contact with the third superconducting layer 46.

The first joint layer 30a between the first superconducting layer 16 and the third superconducting layer 46 and the second joint layer 30b between the second superconducting layer 26 and the third superconducting layer 46 are continuous.

The joint layer 30 is not present, for example, between the first superconducting layer 16 and the second superconducting layer 26. For example, an air gap is present between the first superconducting layer 16 and the second superconducting layer 26. In addition, the first superconducting layer 16 and the second superconducting layer 26 may be in contact with each other.

The joint layer 30 is an oxide superconducting layer. The joint layer 30 contains a rare earth element (RE), barium (Ba), copper (Cu), and oxygen (O). The joint layer 30 contains, for example, a rare earth element (RE), barium (Ba), copper (Cu), and oxygen (O). For example, the joint layer 30 contains at least one rare earth element (RE) in a group consisting of yttrium (Y), lanthanum (La), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

The joint layer 30 according to the second embodiment has the same configuration as the joint layer 30 according to the first embodiment shown in FIG. 2.

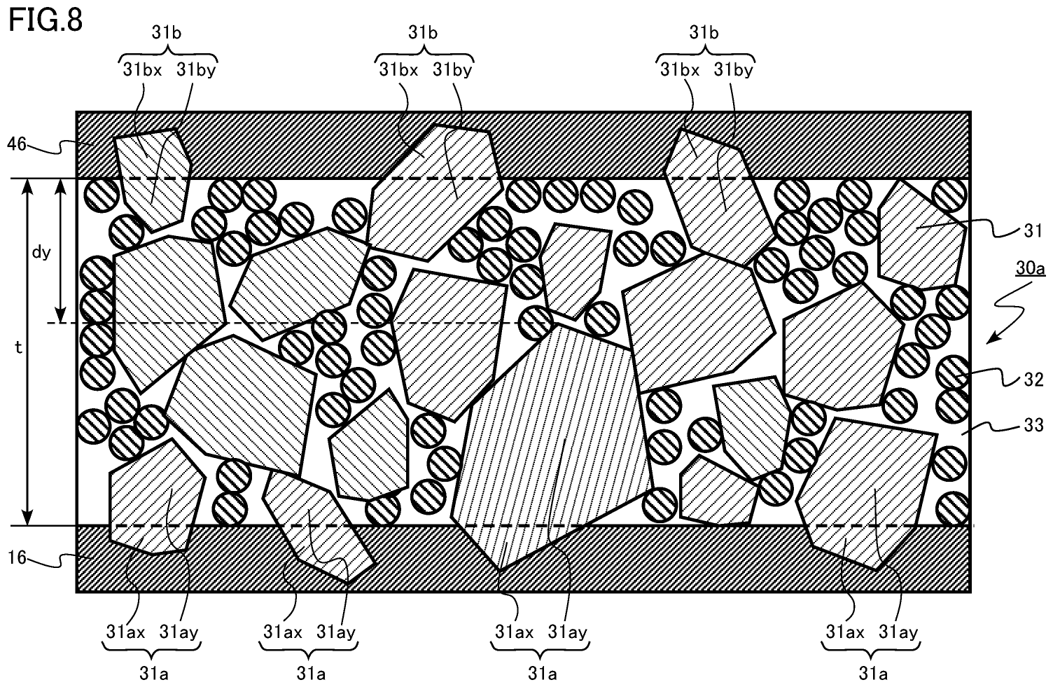

FIG. 8 is an enlarged schematic cross-sectional view of a part of the first joint layer according to the second embodiment. FIG. 8 is a diagram corresponding to FIG. 2 of the first embodiment.

The first joint layer 30a according to the second embodiment is different from the joint layer 30 according to the first embodiment only in that the second superconducting layer 26 in FIG. 2 is replaced with the third superconducting layer 46.

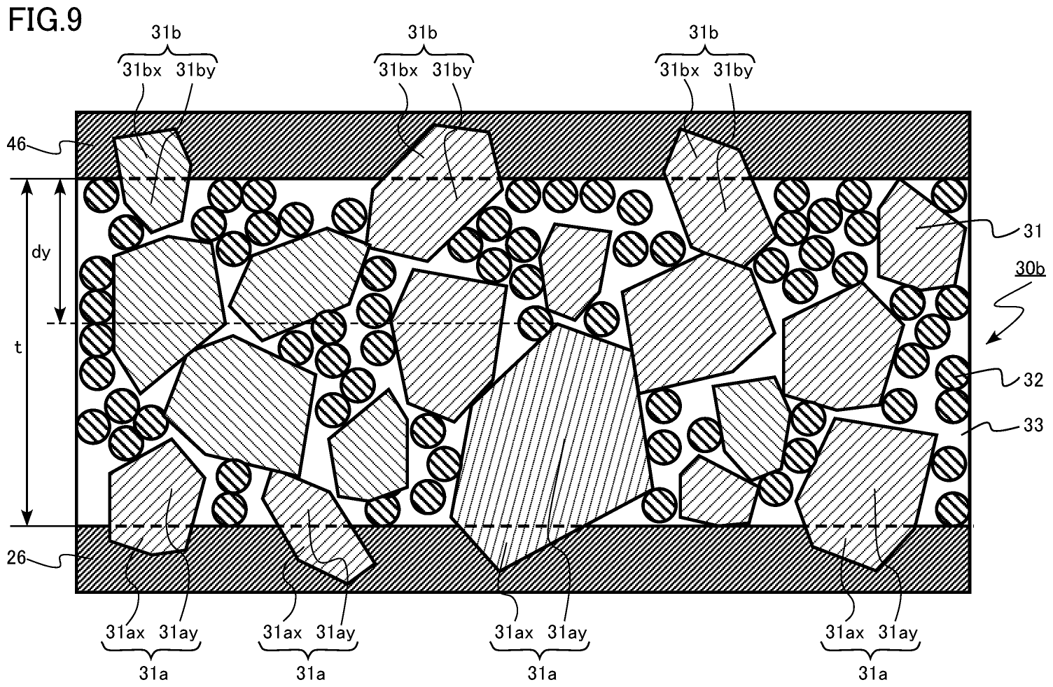

FIG. 9 is an enlarged schematic cross-sectional view of a part of the second joint layer according to the second embodiment. FIG. 9 is a diagram corresponding to FIG. 2 of the first embodiment.

The second joint layer 30b according to the second embodiment is different from the joint layer 30 according to the first embodiment only in that the first superconducting layer 16 in FIG. 2 is replaced with the second superconducting layer 26 and the second superconducting layer 26 in FIG. 2 is replaced with the third superconducting layer 46.

In the superconducting wire 400 according to the second embodiment, for example, the current flows from the first superconducting wire 401 to the second superconducting wire 402 through the first joint layer 30a, the joint member 403, and the second joint layer 30b.

Since the first superconducting wire 401 and the joint member 403 are connected to each other by using the first joint layer 30a, the joint structure that joints the first superconducting wire 401 and the joint member 403 to each other has a low electrical resistance and a high mechanical strength. In addition, since the second superconducting wire 402 and the joint member 403 are connected to each other by using the second joint layer 30b, the joint structure that joints the second superconducting wire 402 and the joint member 403 to each other has a low electrical resistance and a high mechanical strength.

Therefore, the joint structure that joints the first superconducting wire 401 and the second superconducting wire 402 has a low electrical resistance and a high mechanical strength. As a result, the superconducting wire 400 has a low electrical resistance and a high mechanical strength.

In addition, it is also possible to connect three or more superconducting wires to each other to form a longer superconducting wire.

### First Modification Example

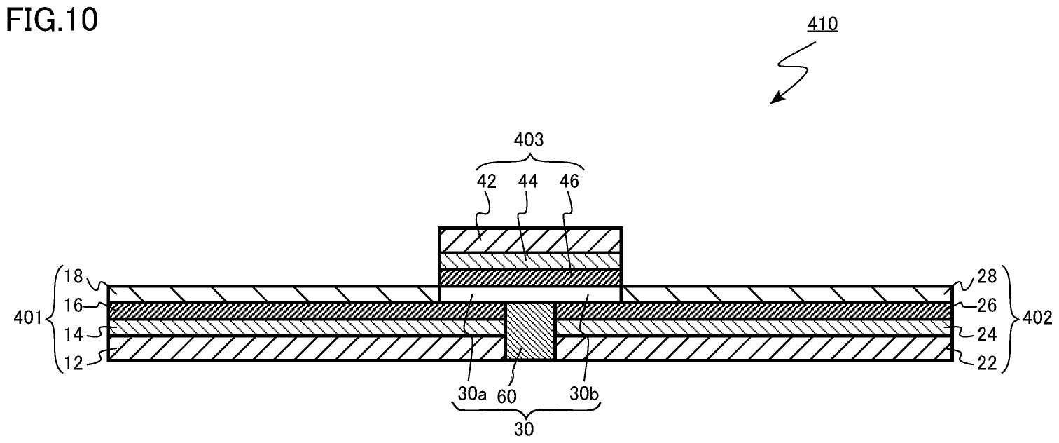

FIG. 10 is a schematic cross-sectional view of a first modification example of the superconducting wire according to the second embodiment. A superconducting wire 410 in the first modification example of the second embodiment is different from the superconducting wire 400 according to the second embodiment in that a reinforcing member 60 is provided.

Reinforcing member 60 is provided between first superconducting wire 401 and second superconducting wire 402. The reinforcing member 60 is provided, for example, between the first superconducting layer 16 and the second superconducting layer 26.

The reinforcing member 60 is in contact with, for example, the first superconducting wire 401 and the second superconducting wire 402. The reinforcing member 60 is in contact with the joint layer 30, for example.

By providing the reinforcing member 60, the mechanical strength of the superconducting wire 410 is improved.

The reinforcing member 60 is, for example, a metal or resin. The reinforcing member 60 is, for example, solder. The reinforcing member 60 is, for example, solder containing silver (Ag) and indium (In).

### Second Modification Example

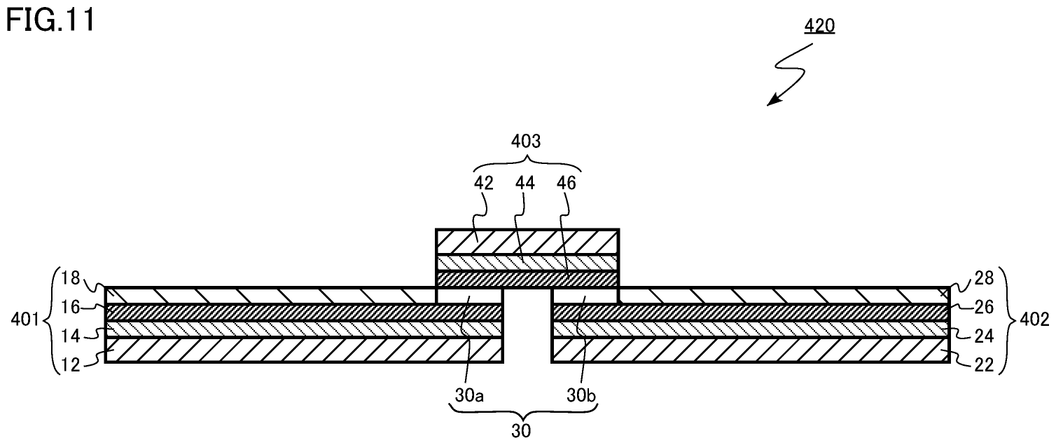

FIG. 11 is a schematic cross-sectional view of a second modification example of the superconducting wire according to the second embodiment. A superconducting wire 420 in the second modification example of the second embodiment is different from the superconducting wire 400 according to the second embodiment in that the first joint layer 30a and the second joint layer 30b are spaced apart from each other.

The first joint layer 30a and the second joint layer 30b are spaced apart from each other.

### Third Modification Example

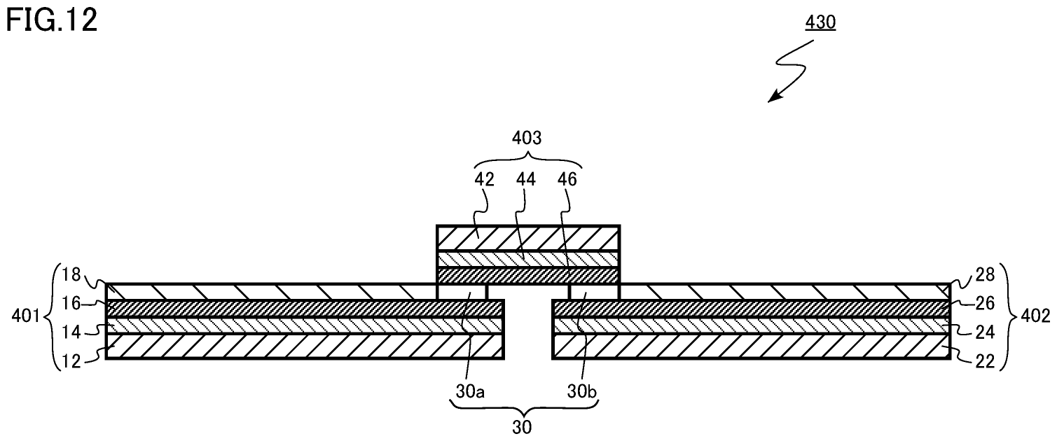

FIG. 12 is a schematic cross-sectional view of a third modification example of the superconducting wire according to the second embodiment. A superconducting wire 430 in a third modification example of the second embodiment is different from the superconducting wire 420 in the second modification example of the second embodiment in that a part of the surface of the first superconducting layer 16 facing the third superconducting layer 46 is exposed and a part of the surface of the second superconducting layer 26 facing the third superconducting layer 46 is exposed.

Near the end on the second superconducting layer 26 side on the upper surface of the first superconducting layer 16, there is a region where there is no joint layer 30. In addition, near the end on the first superconducting layer 16 side on the upper surface of the second superconducting layer 26, there is a region where there is no joint layer 30.

### Fourth Modification Example

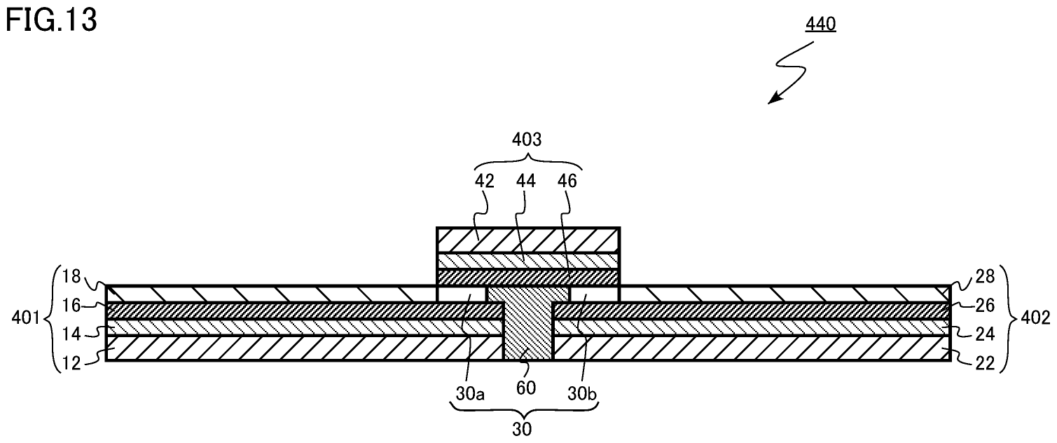

FIG. 13 is a schematic cross-sectional view of a fourth modification example of the superconducting wire according to the second embodiment. A superconducting wire 440 in the fourth modification example of the second embodiment is different from the superconducting wire 430 in the third modification example of the second embodiment in that a reinforcing member 60 is provided.

The reinforcing member 60 is provided between the first superconducting wire 401 and the second superconducting wire 402. The reinforcing member 60 is provided, for example, between the first superconducting layer 16 and the second superconducting layer 26. The reinforcing member 60 is provided, for example, between the first superconducting layer 16 and the third superconducting layer 46. The reinforcing member 60 is provided, for example, between the second superconducting layer 26 and the third superconducting layer 46. The reinforcing member 60 is provided, for example, between the first joint layer 30a and the second joint layer 30b.

By providing the reinforcing member 60, the mechanical strength of the superconducting wire 440 is improved.

The reinforcing member 60 is, for example, a metal or resin. The reinforcing member 60 is, for example, solder. The reinforcing member 60 is, for example, solder containing silver (Ag) and indium (In).

As described above, according to the second embodiment and its modification examples, it is possible to realize a superconducting wire that is lengthened by jointing two superconducting wires to each other and has a low electrical resistance and a high mechanical strength.

### Third Embodiment

A superconducting coil according to a third embodiment includes the superconducting wire according to the second embodiment. Hereinafter, the description of a part of the content overlapping the second embodiment may be omitted.

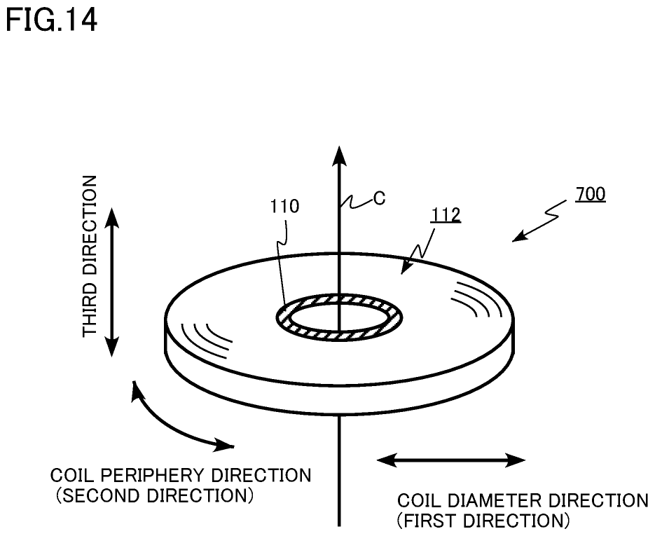

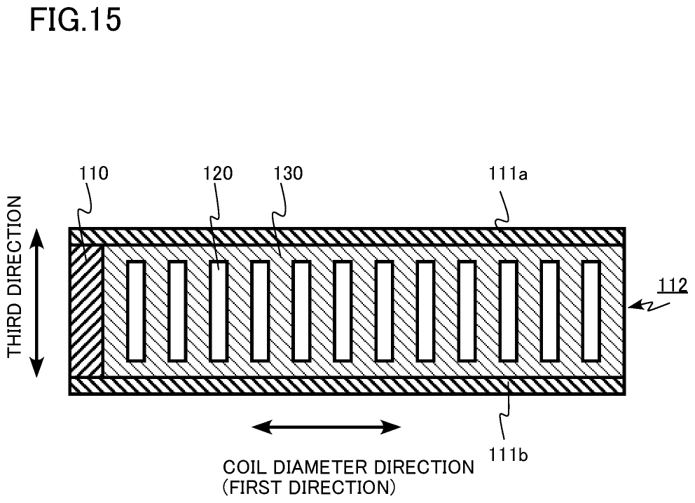

FIG. 14 is a schematic perspective view of the superconducting coil according to the third embodiment. FIG. 15 is a schematic cross-sectional view of the superconducting coil according to the third embodiment.

A superconducting coil 700 according to the third embodiment is used, for example, as a magnetic field generating coil for a superconducting device, such as an NMR, an MRI, a heavy particle beam radiotherapy device, or a superconducting magnetic levitation railway vehicle.

The superconducting coil 700 includes a winding frame 110, a first insulating plate 111a, a second insulating plate 1l1b, and a winding portion 112. The winding portion 112 has a superconducting wire 120 and an inter-wire layer 130.

FIG. 14 shows a state in which the first insulating plate 111a and the second insulating plate 1l1b are removed.

The winding frame 110 is formed of fiber-reinforced plastic, for example. The superconducting wire 120 has, for example, a tape shape. As shown in FIG. 14, the superconducting wire 120 is wound around the winding frame 110 in a concentric so-called pancake shape with the winding central axis C as its axis.

In FIG. 14, the first direction is the coil diameter direction. The second direction is a coil periphery direction. The first direction is a direction in which the winding central axis C extends.

The inter-wire layer 130 has a function of fixing the superconducting wire 120. The inter-wire layer 130 has a function of suppressing the destruction of the superconducting wire 120 due to vibration during use of the superconducting device or friction therebetween.

The first insulating plate 111a and the second insulating plate 1l1b are formed of fiber-reinforced plastic, for example. The first insulating plate 111a and the second insulating plate 1l1b have a function of insulating the winding portion 112 from the outside. The winding portion 112 is disposed between the first insulating plate 111a and the second insulating plate 1l1b.

The superconducting wire according to the second embodiment is used as the superconducting wire 120.

As described above, according to the third embodiment, a superconducting coil having improved characteristics can be realized by providing a superconducting wire having a low electrical resistance and a high mechanical strength.

### Fourth Embodiment

A superconducting device according to a fourth embodiment is a superconducting device including the superconducting coil according to the third embodiment. Hereinafter, the description of a part of the content overlapping the third embodiment will be omitted.

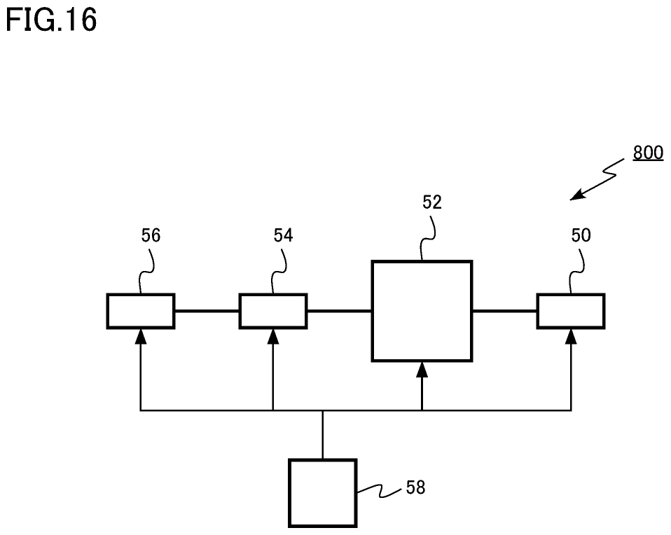

FIG. 16 is a block diagram of the superconducting device according to the fourth embodiment. The superconducting device according to the fourth embodiment is a heavy particle beam radiotherapy device 800. The heavy particle beam radiotherapy device 800 is an example of the superconducting device.

The heavy particle beam radiotherapy device 800 includes an incidence system 50, a synchrotron accelerator 52, a beam transport system 54, an emission system 56, and a control system 58.

The incidence system 50 has a function of, for example, generating carbon ions used for treatment and pre-accelerating the carbon ions to be incident on the synchrotron accelerator 52. The incidence system 50 has, for example, an ion source and a linear accelerator.

The synchrotron accelerator 52 has a function of accelerating the carbon ion beam incident from the incidence system 50 to an energy suitable for treatment. The superconducting coil 700 according to the third embodiment is used as the synchrotron accelerator 52.

The beam transport system 54 has a function of transporting the carbon ion beam incident from the synchrotron accelerator 52 to the emission system 56. The beam transport system 54 has, for example, a deflection electromagnet.

The emission system 56 has a function of emitting the carbon ion beam incident from the beam transport system 54 to a patient who is an emission target. The emission system 56 has, for example, a rotating gantry that allows the carbon ion beam to be emitted from any direction. The superconducting coil 700 according to the third embodiment is used as the rotating gantry.

The control system 58 controls the incidence system 50, the synchrotron accelerator 52, the beam transport system 54, and the emission system 56. The control system 58 is, for example, a computer.

In the heavy particle beam radiotherapy device 800 according to the fourth embodiment, the superconducting coil 700 according to the third embodiment is used as the synchrotron accelerator 52 and the rotating gantry. Therefore, the heavy particle beam radiotherapy device 800 with excellent characteristics is realized.

In the fourth embodiment, as an example of a superconducting device, the case of the heavy particle beam radiotherapy device 800 has been described. However, the superconducting device may be a nuclear magnetic resonance (NMR) apparatus, a magnetic resonance imaging (MRI) apparatus, or a superconducting magnetic levitation railway vehicle.

### EXAMPLES

### Example 1

An intermediate layer and a GdBa₂Cu₃07-6 layer (oxide superconducting layer) were formed on a Hastelloy substrate, and two 10-cm long oxide superconducting wires covered with a protective layer of silver and copper were prepared. A portion of 1.0 cm from one end was wet-etched by using nitric acid and a mixed solution of ammonia and hydrogen peroxide to expose the oxide superconducting layer.

Powders of Gd₂O₃, BaCO₃, and CuO were prepared, properly weighed, and thoroughly mixed, and the mixed powder was compression-molded to prepare a powder compact. By sintering the obtained powder compact at 930° C., an oxide superconductor having a composition of GdBa₂Cu₃O_{7-δ} was manufactured. The obtained oxide superconductor was pulverized by hitting in a mortar, and particles having suitable diameters were selected with a sieve or the like to manufacture a superconductor powder having a long diameter equal to or less than 10 μm and a short diameter equal to or less than 2 μm.

The obtained superconductor powder and an organometallic salt solution in which Gd(OCOCH₃)₂, Ba(OCOCH₃)₂, and Cu(OCOCH₃)₂ were dissolved were mixed at a weight ratio of 1:2 to manufacture a slurry.

The obtained slurry was applied to the exposed oxide superconducting layer of one of the above-described superconducting wires and baked at 780° C. Thereafter, a portion of the superconducting wire applied with the slurry and a portion of another superconducting wire where the superconducting layer was exposed were superimposed face to face.

The superimposed wires were interposed between jigs from above and below and pressed. The pressure value at the time of baking was set to a reference value of 1.0, a pressure value of 1.2 was applied once when the wires were first interposed, and baking was started after reducing the pressure value to 1.0.

A first heat treatment was performed by heating up to 780° C. in an air atmosphere while the wires were interposed between the jigs. Thereafter, the wires were cooled to around room temperature, an oxygen gas was introduced into the furnace, and the furnace was heated to 500° C. in an oxygen atmosphere to perform a second heat treatment, thereby forming a superconducting wire joint structure.

Terminals were attached to both ends of the superconducting wire after joint, and the temperature dependence of the electrical resistance was measured. As a result, a clear superconducting transition was confirmed at around 93 K and a transition width of about 1 K. With the critical current value at 77 K of this joint structure as a reference value of 1.0, relative critical current values are shown in the following examples and comparative examples.

In addition, with the critical current value at 77 K when this joint structure is bent at R=15 cm as a reference value of 1.0, relative critical current values when the joint structures of examples and comparative examples are similarly bent are shown below.

This joint structure was cut in a cross section perpendicular to the surface of the superconducting layer of the superconducting wire, and SEM observation and STEM observation were performed. Some of the superconductor powder contained in the joint layer were buried in the superconducting wire to obtain a first inner region and a first outer region (first particle). From the observed SEM image and STEM image, the area of the first inner region (S1), the area of the first outer region (S2), and the ratio α (S1/(S1+S2)) of the area of the first inner region to the sum of the area of the first inner region and the area of the first outer region were calculated. The result was S2>S1 and α=10%.

From the observed STEM image, the angle θ between the c-axis direction of one first particle and the c-axis direction of the first superconducting layer in which the particle was buried was 15°.

From the observed SEM image, the distance between one first particle and the second superconducting layer was ½ of the distance between the first superconducting layer and the second superconducting layer (the thickness of the joint layer) (described as a distance ratio β). In addition, the particle diameter of one first particle was 5 μm. In addition, the depth of the first inner region from the surface of the first superconducting layer was 1.0 μm (described as a burial depth). The number of first particles present in the range of 1 mm along the surface of the first superconducting layer was 10.

As a result of measurement of the particle size distribution, the first peak was 5 μm and the second peak was 100 nm.

These characteristics are shown in Table 1.

TABLE 1

| | | | | | | Relative | | |
|---|---|---|---|---|---|---|---|---|
| | | | | | | critical | | |
| | | Relative | Relative | | Relative | current | | |
| | Mixing ratio of | pressure | pressure | | critical | value at | | |
| | powder and | value | value | Temperature | current | 77K | Ratio of | Area |
| | organometallic | before | during | of first heat | value at | during | S1 and | ratio |
| | salt solution | baking | baking | treatment | 77K | bending | S2 | α |
| Example 1 | 1:2 | 1.2 | 1.0 | 780° C. | 1.0 | 1.0 | S2 > S1 | 10% |
| Comparative | Solution only | 1.2 | 1.0 | 780° C. | 0.8 | 0.2 | — | 0% |
| Example 1 | | | | | | | | |
| Comparative | 1:4 | 1.0 | 1.0 | 780° C. | 0.8 | 0.5 | — | 0% |
| Example 2 | | | | | | | | |
| Example 2 | 1:2 | 1.5 | 1.0 | 800° C. | 1.2 | 1.2 | S2 > S1 | 90% |
| Example 3 | 1:2 | 1.1 | 1.0 | 780° C. | 1.0 | 0.9 | S2 > S1 | 8% |
| Example 4 | 1:2 | 2.0 | 1.0 | 820° C. | 0.8 | 0.8 | S1 > S2 | 92% |
| Example 5 | 1:2 | 1.2 | 1.0 | 780° C. | 0.9 | 0.9 | S2 > S1 | 10% |
| Example 6 | 1:2 | 1.2 | 1.0 | 780° C. | 1.0 | 1.0 | S2 > S1 | 10% |
| Example 7 | 1:2 | 1.0 | 1.0 | 770° C. | 0.8 | 0.7 | S2 > S1 | 10% |
| Example 8 | 1:2 | 1.4 | 1.0 | 790° C. | 0.7 | 0.7 | S2 > S1 | 11% |
| Example 9 | 1:1 | 1.2 | 1.0 | 780° C. | 0.9 | 0.7 | S2 > S1 | 10% |
| Example 10 | 1:2 | 1.2 | 1.0 | 780° C. | 0.9 | 0.9 | S2 > S1 | 10% |
| Example 11 | 1:3 | 1.2 | 1.0 | 780° C. | 1.0 | 1.0 | S2 > S1 | 10% |
| Example 12 | 1:1 | 1.2 | 1.0 | 780° C. | 1.2 | 1.2 | S2 > S1 | 25% |
| Example 13 | 2:1 | 1.2 | 1.0 | 780° C. | 1.2 | 1.2 | S2 > S1 | 40% |
| Example 14 | 3:1 | 1.2 | 1.0 | 780° C. | 1.0 | 1.0 | S2 > S1 | 85% |
| Example 15 | 1:2 | 1.2 | 0.9 | 780° C. | 0.9 | 0.8 | S2 > S1 | 7% |
| Example 16 | 1:2 | 1.2 | 1.2 | 780° C. | 0.9 | 0.9 | S2 > S1 | 13% |

| | | | Particle | | | | | | | Second peak |
|---|---|---|---|---|---|---|---|---|---|---|
| | | | diameter | | | | Number | First peak of | | of particle |
| | | Distance | of first | | | | of first | particle size | | size |
| | θ | ratio β | particle | | Burial depth | | particle | distribution | | distribution |
| Example 1 | 15° | 1/2 | 5 μm | | 1.5 | μm | 10 | 5 | μm | 100 nm |
| Comparative | — | — | — | | — | | 0 | — | | 100 nm |
| Example 1 | | | | | | | | | | |
| Comparative | — | — | — | | — | | 0 | 5 | μm | 100 nm |
| Example 2 | | | | | | | | | | |
| Example 2 | 30° | 1/2 | 500 | nm | 200 | nm | 22 | 500 | nm | 200 nm |
| Example 3 | 15° | 1/2 | 5 | μm | 1.0 | μm | 9 | 5 | μm | 100 nm |
| Example 4 | 40° | 3/4 | 500 | nm | 400 | nm | 95 | 500 | nm | 350 nm |
| Example 5 | 10° | 1/3 | 5 | μm | 500 | nm | 10 | 5 | μm | 100 nm |
| Example 6 | 15° | 1/2 | 500 | nm | 100 | nm | 11 | 500 | nm | 100 nm |
| Example 7 | 15° | 1/2 | 5 | μm | 90 | nm | 10 | 5 | μm | 100 nm |
| Example 8 | 20° | 1/4 | 5 | μm | 1.7 | μm | 10 | 5 | μm | 140 nm |
| Example 9 | 80° | 2/3 | 200 | nm | 50 | nm | 15 | 400 | nm | 100 nm |
| Example 10 | 15° | 1/3 | 6 | μm | 1.5 | μm | 10 | 6 | μm | 100 nm |
| Example 11 | 15° | 1/2 | 5 | μm | 1.5 | μm | 10 | 5 | μm | 100 nm |
| Example 12 | 50° | 1/2 | 5 | μm | 1.5 | μm | 10 | 5 | μm | 100 nm |
| Example 13 | 15° | 1/4 | 5 | μm | 1.5 | μm | 30 | 5 | μm | 100 nm |
| Example 14 | 65° | 1/4 | 5 | μm | 1.5 | μm | 36 | 5 | μm | 100 nm |
| Example 15 | 15° | 1/2 | 5 | μm | 700 | nm | 8 | 5 | μm | 100 nm |
| Example 16 | 15° | 1/2 | 5 | μm | 1.6 | μm | 14 | 5 | μm | 170 nm |

### Comparative Example 1

An intermediate layer and a GdBa₂Cu₃O_{7-δ} layer (oxide superconducting layer) were formed on a Hastelloy substrate, and two 10-cm long oxide superconducting wires covered with a protective layer of silver and copper were prepared. A portion of 1.0 cm from one end was wet-etched by using nitric acid and a mixed solution of ammonia and hydrogen peroxide to expose the oxide superconducting layer.

An organometallic salt solution in which Gd(OCOCH₃)₂, Ba(OCOCH₃)₂, and Cu(OCOCH₃)₂ were dissolved was applied to the exposed oxide superconducting layer of one of the superconducting wires described above, and then was baked at 780° C. A portion of the superconducting wire applied with the slurry and a portion of another superconducting wire where the superconducting layer was exposed were superimposed face to face.

The superimposed wires were interposed between jigs from above and below, and were once pressed at a relative pressure value of 1.2. Then, the relative pressure value was set to 1.0.

A first heat treatment was performed by heating up to 780° C. in an air atmosphere while the wires were interposed between the jigs. Thereafter, the wires were cooled to around room temperature, an oxygen gas was introduced into the furnace, and the furnace was heated to 500° C. in an oxygen atmosphere to perform a second heat treatment, thereby forming a superconducting wire joint structure.

The results of electrical resistance measurement, SEM observation, STEM observation, and particle size distribution measurement performed in the same manner as in Example 1 are shown in Table 1. In this joint structure, the particle size distribution had one peak, and the particle diameter at the peak was 100 nm, the joint layer was formed by only fine particles. In addition, none of these particles were buried in the superconducting layer. The characteristics are shown in Table 1.

### Comparative Example 2

A joint structure was formed and evaluated in the same manner as in Example 1, except that the weight ratio between the superconductor powder and the organometallic salt solution was set to 1:4 and the pressure value before baking was set to 1.0. In this joint structure, none of the particles forming the joint layer were buried in the superconducting layer.

### Example 2

A joint structure was formed and evaluated in the same manner as in Example 1, except that an oxide superconductor having a GdBa₂Cu₃O₇-6 composition was manufactured and pulverized and then particles having long diameters equal to or less than 1 μm were selected with a sieve or the like, the pressure value before baking was set to 1.5, and the first heat treatment temperature was set to 800° C.

### Example 3

A joint structure was formed and evaluated in the same manner as in Example 1, except that the relative pressure value before baking was set to 1.1.

### Example 4

A joint structure was formed and evaluated in the same manner as in Example 1, except that the relative pressure value before baking was set to 2.0 and the temperature of the first heat treatment was set to 820° C.

### Example 5

A joint structure was formed and evaluated in the same manner as in Example 1, except that after manufacturing the superconductor powder having a long diameter equal to or less than 10 μm and a short diameter equal to or less than 2 μm, a plate-shaped superconductor powder having a thickness equal to or less than 1 μm was further selected.

### Example 6

A joint structure was formed and evaluated in the same manner as in Example 1, except that an oxide superconductor having a GdBa₂Cu₃O₇-6 composition was manufactured and pulverized and then particles having long diameters equal to or less than 1 μm were selected with a sieve or the like.

### Example 7

A joint structure was formed and evaluated in the same manner as in Example 1, except that the relative pressure value before baking was set to 1.0 and the temperature of the first heat treatment was set to 770° C.

### Example 8

A joint structure was formed and evaluated in the same manner as in Example 1, except that the relative pressure value before baking was set to 1.4 and the temperature of the first heat treatment was set to 790° C.

### Example 9

A joint structure was formed and evaluated in the same manner as in Example 1, except that an oxide superconductor having a GdBa₂Cu₃O₇-6 composition was manufactured and pulverized and then particles having long diameters equal to or less than 0.5 μm were selected with a sieve or the like.

### Example 10

A joint structure was formed and evaluated in the same manner as in Example 1, except that an oxide superconductor having a GdBa₂Cu₃O₇-6 composition was manufactured and pulverized and then particles having long diameters equal to or less than 15 μm were selected with a sieve or the like.

### Examples 11 to 14

A joint structure was formed and evaluated in the same manner as in Example 1, except that the weight ratio between the superconductor powder and the organometallic salt solution was changed as shown in Table 1.

### Examples 15 and 16

A joint structure was formed and evaluated in the same manner as in Example 1, except that the relative pressure value at the time of baking was changed as shown in Table 1.

From the above, it can be seen that Examples 1 to 16 having a superconducting layer joint structure in which at least one particle has a first inner region and a first outer region, the first inner region is disposed inside the first superconducting layer, and the first outer region is disposed outside the first superconducting layer have a lower electrical resistance and a higher mechanical strength than Comparative Examples 1 and 2 which do not have particles with portions present in both the superconducting layer and the joint layer.

In addition, as shown in Table 1, Examples 1, 2, 6, 11, 12, 13, and 14 in which the area ratio α is equal to or more than 10% and equal to or less than 90%, S2>S1, the angle θ is equal to or more than 15°, a bimodal is applied, and the distance ratio β is equal to or less than ½, the particle diameter of the first particles is equal to or more than 500 nm and equal to or less than 5 μm, the burial depth is equal to or more than 100 nm and equal to or less than 1.5 μm, and the number of first particles is equal to or more than 10 have a higher relative critical current value at 77K or a higher relative critical current value at 77K at the time of bending than Examples 3 to 5, 7 to 10, 15, and 16 outside any of the ranges described above. Therefore, Examples 1, 2, 6, 11, 12, 13, and 14 were found to have a lower electrical resistance or a higher mechanical strength than Examples 3 to 5, 7 to 10, 15, and 16.

In addition, Examples 2, 12 and 13 were found to have a particularly low electrical resistance and a particularly high mechanical strength.

While certain embodiments have been described, these embodiments have been presented by way of example only, and are not intended to limit the scope of the inventions. Indeed, the superconducting layer joint structure, the superconducting wire, the superconducting coil, and the superconducting device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

Hereinafter, technical proposals that are examples of embodiments will be described.

(Technical Proposal 1)

A superconducting layer joint structure including: a first superconducting layer; a second superconducting layer; and a joint layer provided between the first superconducting layer and the second superconducting layer and containing a plurality of crystal particles containing a rare earth element (RE), barium (Ba), copper (Cu), and oxygen (O), in which the plurality of crystal particles include at least one first particle, the at least one first particle has a first inner region and a first outer region, the first inner region is disposed inside the first superconducting layer, and the first outer region is disposed outside the first superconducting layer.

(Technical Proposal 2)

The superconducting layer joint structure described in Technical Proposal 1, in which, in a cross section perpendicular to a surface of the first superconducting layer, a ratio of an area of the first inner region to a sum of an area of the first inner region and an area of the first outer region is equal to or more than 10% and equal to or less than 90%.

(Technical Proposal 3)

The superconducting layer joint structure described in Technical Proposal 1 or 2, in which, in a cross section perpendicular to a surface of the first superconducting layer, an area of the first outer region is larger than an area of the first inner region.

(Technical Proposal 4)

The superconducting layer joint structure described in any one of Technical Proposals 1 to 3, in which an angle between a c-axis direction of the at least one first particle and a c-axis direction of the first superconducting layer is equal to or more than 15°.

(Technical Proposal 5)

The superconducting layer joint structure described in any one of Technical Proposals 1 to 4, in which a particle diameter distribution of the plurality of crystal particles includes a bimodal distribution.

(Technical Proposal 6)

The superconducting layer joint structure described in Technical Proposal 5, in which the bimodal distribution has a first distribution including a first peak and a second distribution including a second peak, a first particle diameter corresponding to the first peak is larger than a second particle diameter corresponding to the second peak, and the at least one first particle is included in the first distribution.

(Technical Proposal 7)

The superconducting layer joint structure described in any one of Technical Proposals 1 to 6, in which a distance between the at least one first particle and the second superconducting layer is equal to or less than ½ of a distance between the first superconducting layer and the second superconducting layer.

(Technical Proposal 8)

The superconducting layer joint structure described in any one of Technical Proposals 1 to 7, in which the at least one first particle is in contact with the second superconducting layer.

(Technical Proposal 9)

The superconducting layer joint structure described in any one of Technical Proposals 1 to 8, in which the plurality of crystal particles includes at least one second particle, the at least one second particle has a second inner region and a second outer region, the second inner region is disposed inside the second superconducting layer, and the second outer region is disposed outside the second superconducting layer.

(Technical Proposal 10)

The superconducting layer joint structure described in any one of Technical Proposals 1 to 9, in which the at least one first particle has a particle diameter equal to or more than 500 nm and equal to or less than 5 μm.

(Technical Proposal 11)

The superconducting layer joint structure described in any one of Technical Proposals 1 to 10, in which, in a cross section perpendicular to a surface of the first superconducting layer, a depth of the first inner region from the surface of the first superconducting layer is equal to or more than 100 nm and equal to or less than 1.5 μm.

(Technical Proposal 12)

The superconducting layer joint structure described in any one of Technical Proposals 1 to 11, in which, in a cross section perpendicular to a surface of the first superconducting layer, the number of the at least one first particle present in a range of 1 mm along the surface is equal to or more than 10.

(Technical Proposal 13)

A superconducting wire including: a first superconducting wire including a first superconducting layer; a second superconducting wire including a second superconducting layer; a third superconducting layer; a first joint layer provided between the first superconducting layer and the third superconducting layer and containing a plurality of crystal particles containing a rare earth element (RE), barium (Ba), copper (Cu), and oxygen (O); and a second joint layer provided between the second superconducting layer and the third superconducting layer and containing a plurality of crystal particles containing a rare earth element (RE), barium (Ba), copper (Cu), and oxygen (O), in which the plurality of crystal particles contained in the first joint layer include at least one first particle, the at least one first particle has a first inner region and a first outer region, the first inner region is disposed inside the first superconducting layer, and the first outer region is disposed outside the first superconducting layer.

(Technical Proposal 14)

The superconducting wire described in Technical Proposal 13, in which, in a cross section perpendicular to a surface of the first superconducting layer, a ratio of an area of the first inner region to a sum of an area of the first inner region and an area of the first outer region is equal to or more than 10%.

(Technical Proposal 15)

The superconducting wire described in Technical Proposal 13 or 14, in which, in a cross section perpendicular to a surface of the first superconducting layer, an area of the first outer region is larger than an area of the first inner region.

(Technical Proposal 16)

The superconducting wire described in any one of Technical Proposals 13 to 15, in which an angle between a c-axis direction of the at least one first particle and a c-axis direction of the first superconducting layer is equal to or more than 15°.

(Technical Proposal 17)

The superconducting wire described in any one of Technical Proposals 13 to 16, in which a particle diameter distribution of the plurality of crystal particles contained in the first joint layer includes a bimodal distribution.

(Technical Proposal 18)

The superconducting wire described in Technical Proposal 17, in which the bimodal distribution has a first distribution including a first peak and a second distribution including a second peak, a first particle diameter corresponding to the first peak is larger than a second particle diameter corresponding to the second peak, and the at least one first particle is included in the first distribution.

(Technical Proposal 19)

A superconducting coil including the superconducting wire described in any one of Technical Proposals 13 to 18.

(Technical Proposal 20)

A superconducting device including the superconducting coil described in Technical Proposal 19.

What is claimed is:

1. A superconducting layer joint structure, comprising:
a first superconducting layer;
a second superconducting layer; and
a joint layer provided between the first superconducting layer and the second superconducting layer and containing a plurality of crystal particles containing a rare earth element (RE), barium (Ba), copper (Cu), and oxygen (O),
wherein the plurality of crystal particles includes at least one first particle, the at least one first particle has a first inner region and a first outer region, the first inner region is disposed inside the first superconducting layer, and the first outer region is disposed outside the first superconducting layer.

2. The superconducting layer joint structure according to claim 1,
wherein, in a cross section perpendicular to a surface of the first superconducting layer, a ratio of an area of the first inner region to a sum of an area of the first inner region and an area of the first outer region is equal to or more than 10% and equal to or less than 90%.

3. The superconducting layer joint structure according to claim 1,
wherein, in a cross section perpendicular to a surface of the first superconducting layer, an area of the first outer region is larger than an area of the first inner region.

4. The superconducting layer joint structure according to claim 1,
wherein an angle between a c-axis direction of the at least one first particle and a c-axis direction of the first superconducting layer is equal to or more than 15°.

5. The superconducting layer joint structure according to claim 1,
wherein a particle diameter distribution of the plurality of crystal particles includes a bimodal distribution.

6. The superconducting layer joint structure according to claim 5,
wherein the bimodal distribution has a first distribution including a first peak and a second distribution including a second peak, a first particle diameter corresponding to the first peak is larger than a second particle diameter corresponding to the second peak,
and the at least one first particle is included in the first distribution.

7. The superconducting layer joint structure according to claim 1,
wherein a distance between the at least one first particle and the second superconducting layer is equal to or less than ½ of a distance between the first superconducting layer and the second superconducting layer.

8. The superconducting layer joint structure according to claim 1,
wherein the at least one first particle is in contact with the second superconducting layer.

9. The superconducting layer joint structure according to claim 1,
wherein the plurality of crystal particles includes at least one second particle, the at least one second particle has a second inner region and a second outer region, the second inner region is disposed inside the second superconducting layer, and the second outer region is disposed outside the second superconducting layer.

10. The superconducting layer joint structure according to claim 1,
wherein the at least one first particle has a particle diameter equal to or more than 500 nm and equal to or less than 5 μm.

11. The superconducting layer joint structure according to claim 1,
wherein, in a cross section perpendicular to a surface of the first superconducting layer, a depth of the first inner region from the surface of the first superconducting layer is equal to or more than 100 nm and equal to or less than 1.5 μm.

12. The superconducting layer joint structure according to claim 1,
wherein, in a cross section perpendicular to a surface of the first superconducting layer, the number of the at least one first particle present in a range of 1 mm along the surface is equal to or more than 10.

13. A superconducting wire, comprising:
a first superconducting wire including a first superconducting layer;
a second superconducting wire including a second superconducting layer;
a third superconducting layer;
a first joint layer provided between the first superconducting layer and the third superconducting layer and containing a plurality of crystal particles containing a rare earth element (RE), barium (Ba), copper (Cu), and oxygen (O); and
a second joint layer provided between the second superconducting layer and the third superconducting layer and containing a plurality of crystal particles containing a rare earth element (RE), barium (Ba), copper (Cu), and oxygen (O),
wherein the plurality of crystal particles contained in the first joint layer includes at least one first particle, the at least one first particle has a first inner region and a first outer region, the first inner region is disposed inside the first superconducting layer, and the first outer region is disposed outside the first superconducting layer.

14. The superconducting wire according to claim 13,
wherein, in a cross section perpendicular to a surface of the first superconducting layer, a ratio of an area of the first inner region to a sum of an area of the first inner region and an area of the first outer region is equal to or more than 10%.

15. The superconducting wire according to claim 13,
wherein, in a cross section perpendicular to a surface of the first superconducting layer, an area of the first outer region is larger than an area of the first inner region.

16. The superconducting wire according to claim 13,
wherein an angle between a c-axis direction of the at least one first particle and a c-axis direction of the first superconducting layer is equal to or more than 15°.

17. The superconducting wire according to claim 13,
wherein a particle diameter distribution of the plurality of crystal particles contained in the first joint layer includes a bimodal distribution.

18. The superconducting wire according to claim 17,
wherein the bimodal distribution has a first distribution including a first peak and a second distribution including a second peak, a first particle diameter corresponding to the first peak is larger than a second particle diameter corresponding to the second peak, and the at least one first particle is included in the first distribution.

19. A superconducting coil, comprising:
the superconducting wire according to claim 13.

20. A superconducting device, comprising:
the superconducting coil according to claim 19.
